(19) United States
(12) Patent Application Publication
(10) Pub. No.: US 2024/0379043 A1
(43) Pub. Date: Nov. 14, 2024

(54) DISPLAY PANEL AND DISPLAY DEVICE

(71) Applicant: Xiamen Tianma Display Technology Co., Ltd., Xiamen (CN)

(72) Inventors: Qingjun LAI, Xiamen (CN); Chengxu LI, Xiamen (CN)

(73) Assignee: Xiamen Tianma Display Technology Co., Ltd., Xiamen (CN)

(21) Appl. No.: 18/783,337

(22) Filed: Jul. 24, 2024

(30) Foreign Application Priority Data
Jul. 28, 2023 (CN) 202310942643.7

(51) Int. Cl. G09G 3/20; G11C 19/28

(52) U.S. Cl. CPC G09G 3/2092; G09G 2310/0286; G09G 2310/08; G09G 2330/021; G11C 19/287

(57) ABSTRACT

Provided are a display panel and a display device. The display panel includes a drive circuit including cascaded N stage shift registers. A shift register includes a control unit, an initial output unit and a first output unit. The control unit is configured to at least receive an input signal and control a signal of the first output node and a signal of the second output node. The initial output unit is configured to at least receive a signal of the first output node and a signal of the second output node, and control an initial output signal; the initial output signal of an x^{th} stage shift register is the input signal of a y^{th} stage shift register. The first output unit is configured to at least receive the signal of the first output node and the signal of the second output node, and control a first output signal.

### CROSS-REFERENCE TO RELATED APPLICATIONS

This application claims priority to Chinese patent application No. 202310942643.7 filed with the China National Intellectual Property Administration (CNIPA) on Jul. 28, 2023, the disclosure of which is incorporated herein by reference in its entirety.

### TECHNICAL FIELD

The present disclosure relates to the field of display technologies and, in particular, a display panel and a display device.

### BACKGROUND

With the development of display technologies, electronic products having a display function are widely applied to various fields. Televisions, mobile phones, computers, and personal digital assistants are all electronic products that have the display function and become an indispensable part of people's lives and work. A display panel is the core structure for implementing the display function in each electronic product.

Generally, a pixel array and a drive circuit for driving the pixel array are provided in the display panel, and the drive circuit can implement scanning for the pixel array row by row to allow the pixel array to perform image display. However, due to the function and structure of the drive circuit in the related art, the drive modes of rows of pixels in the pixel array are made identical, so that the display panel cannot meet diversified display requirements.

### SUMMARY

A display panel and a display device are provided according to the present disclosure to enable the display panel to meet diversified functional requirements and broaden the application scenario of the display panel.

According to one aspect of the present disclosure, a display panel is provided, which includes a drive circuit.

The drive circuit includes cascaded N stages of shift registers, where N≥2.

A shift register includes a control unit, an initial output unit and a first output unit.

The control unit is configured to at least receive an input signal and control a signal of the first output node and a signal of the second output node.

The initial output unit is configured to at least receive the signal of the first output node and the signal of the second output node, and control an initial output signal, and the initial output signal of an x^{th} stage shift register is the input signal of a y^{th} stage shift register, 1≤x≤N, and 1≤y≤N.

The first output unit is configured to at least receive the signal of the first output node and the signal of the second output node, and control a first output signal.

According to another aspect of the present disclosure, a display device is provided, which includes the above-described display panel.

It is to be appreciated that the contents described in this part are not intended to identify key or important features of the embodiments of the present disclosure, and are not intended to limit the scope of the present disclosure. Other features of the present disclosure will become readily understood through the description hereinafter.

### BRIEF DESCRIPTION OF DRAWINGS

To illustrate technical solutions in embodiments of the present disclosure more clearly, drawings used in description of the embodiments are briefly described hereinafter. Apparently, the drawings described hereinafter merely illustrate some embodiments of the present disclosure, and for the person of ordinary skill in the art, other drawings can be obtained based on these drawings on the premise that no creative efforts are made.

FIG. 1 is a schematic structural diagram of a display panel in the related art.

FIG. 2 is a schematic structural diagram of a display panel according to an embodiment of the present disclosure;

FIG. 3 is a schematic structural diagram of a shift register according to an embodiment of the present disclosure;

FIG. 4 is a drive timing diagram of a shift register according to an embodiment of the present disclosure;

FIG. 5 is a drive timing diagram of another shift register according to an embodiment of the present disclosure;

FIG. 6 is a drive timing diagram of a drive circuit according to an embodiment of the present disclosure;

FIG. 7 is a schematic structural diagram of another shift register according to an embodiment of the present disclosure;

FIG. 8 is a schematic structural diagram of another shift register according to an embodiment of the present disclosure;

FIG. 9 is a schematic structural diagram of another shift register according to an embodiment of the present disclosure;

FIG. 10 is a schematic structural diagram of another shift register according to an embodiment of the present disclosure;

FIG. 11 is a schematic structural diagram of another shift register according to an embodiment of the present disclosure;

FIG. 12 is a schematic structural diagram of another shift register according to an embodiment of the present disclosure;

FIG. 13 is a schematic structural diagram of another shift register according to an embodiment of the present disclosure;

FIG. 14 is a schematic structural diagram of another shift register according to an embodiment of the present disclosure;

FIG. 15 is a schematic structural diagram of another shift register according to an embodiment of the present disclosure;

FIG. 16 is a schematic structural diagram of another shift register according to an embodiment of the present disclosure;

FIG. 17 is a drive timing diagram of a shift register according to an embodiment of the present disclosure;

FIG. 18 is a drive timing diagram of another shift register according to an embodiment of the present disclosure;

FIG. 19 is a schematic structural diagram of a pixel circuit according to an embodiment of the present disclosure;

FIG. 20 is a schematic structural diagram of another pixel circuit according to an embodiment of the present disclosure;

FIG. 21 is a schematic structural diagram of another pixel circuit according to an embodiment of the present disclosure;

FIG. 22 is a schematic structural diagram of another pixel circuit according to an embodiment of the present disclosure;

FIG. 23 is a schematic structural diagram of another pixel circuit according to an embodiment of the present disclosure;

FIG. 24 is a schematic structural diagram of another pixel circuit according to an embodiment of the present disclosure;

FIG. 25 is a drive timing diagram of another shift register according to an embodiment of the present disclosure;

FIG. 26 is a drive timing diagram of another shift register according to an embodiment of the present disclosure;

FIG. 27 is a drive timing diagram of another shift register according to an embodiment of the present disclosure;

FIG. 28 is a schematic structural diagram of another display panel according to an embodiment of the present disclosure;

FIG. 29 is a drive timing diagram of another drive circuit according to an embodiment of the present disclosure;

FIG. 30 is a schematic structural diagram of another display panel according to an embodiment of the present disclosure;

FIG. 31 is a drive timing diagram of another drive circuit according to an embodiment of the present disclosure;

FIG. 32 is a schematic structural diagram of another display panel according to an embodiment of the present disclosure;

FIG. 33 is drive timing diagram of another drive circuit according to an embodiment of the present disclosure;

FIG. 34 is a schematic structural diagram of another shift register according to an embodiment of the present disclosure;

FIG. 35 is a schematic structural diagram of another shift register according to an embodiment of the present disclosure;

FIG. 36 is a schematic structural diagram of another shift register according to an embodiment of the present disclosure;

FIG. 37 is a schematic structural diagram of another shift register according to an embodiment of the present disclosure;

FIG. 38 is a drive timing diagram of another shift register according to an embodiment of the present disclosure;

FIG. 39 is a drive timing diagram of another shift register according to an embodiment of the present disclosure;

FIG. 40 is a schematic structural diagram of another shift register according to an embodiment of the present disclosure;

FIG. 41 is a drive timing diagram of another shift register according to an embodiment of the present disclosure; and

FIG. 42 is a schematic structural diagram of a display device according to an embodiment of the present disclosure.

### DETAILED DESCRIPTION

To enable the person skilled in the art to better understand the technical solutions of the present disclosure, the technical solutions in the embodiments of the present disclosure are described clearly and completely in conjunction with the drawings in the embodiments of the present disclosure. Apparently, the embodiments described below are part, rather than all, of the embodiments of the present disclosure. Based on the embodiments in the present disclosure, all other embodiments obtained by the person skilled in the art on the premise that no creative efforts are made are within the scope of the present disclosure.

It is to be noted that the terms “first”, “second” and the like in the description, claims and the above drawings of the present disclosure are intended to distinguish between similar objects and are not necessarily used to describe a particular order or sequence. It is to be appreciated that the data used in this way is interchangeable where appropriate so that the embodiments of the present disclosure described herein may also be implemented in a sequence besides those sequences illustrated or described herein. Furthermore, terms such as “include”, “have”; and any deformation thereof, are intended to cover non-exclusive inclusion, e.g., a process, method, system, product, or device including a series of steps or units is not necessarily limited to those steps or units expressly listed, but may include other steps or units not expressly listed or inherent to such process, method, system, product or device.

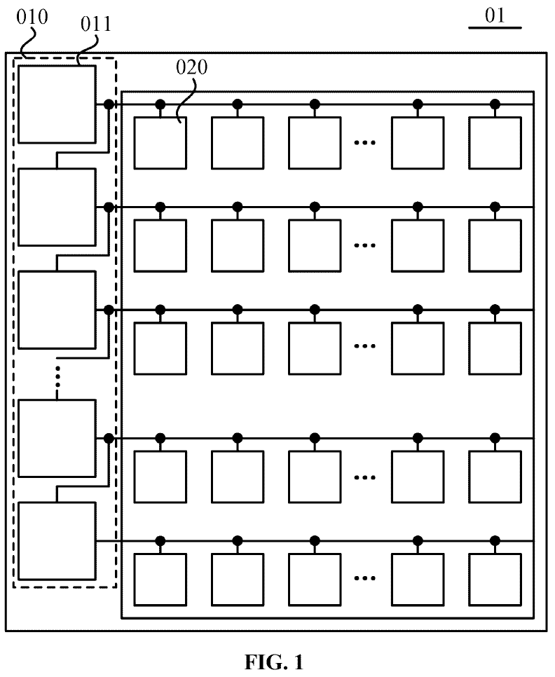

As described in the background, FIG. 1 is a schematic structural diagram of a display panel in the related art. As shown in FIG. 1, the display panel 01 is provided with a drive circuit 010 and pixel circuits 020 arranged in an array. The drive circuit 010 includes multiple shift registers 011 arranged in a cascaded manner, and a drive signal output terminal of each stage shift register 011 may further be electrically connected to the pixel circuits located in the same row as this shift register 011 for providing a drive signal to the pixel circuits in the same row, thus implementing scanning for the pixel circuits row by row. Moreover, since the connection manner of the cascaded shift registers 011 is that a drive signal output terminal of the current stage shift register 011 is electrically connected to a signal input terminal of the next stage shift register 011, the effective pulses of the drive signals output by shift registers 011 of all stages shift sequentially, and the frequency of the drive signal output by the shift register 011 of each stage is the same. As a result, the drive cycles of the pixel circuits 020 controlled by the drive signal are the same, that is, the data signals written into the pixel circuits 020 are refreshed at the same time, so that it is impossible to flexibly control the pixel circuits 020 based on different application scenarios, for example, it is impossible to make pixel circuits 020 in different display regions have different data refresh rates, thus, the display panel 01 cannot meet diversified display requirements, and the application scenario of the display panel is limited.

To address the above-described technical issue, a display panel is provided according to an embodiment of the present disclosure and includes a drive circuit. The drive circuit includes N cascaded stages of shift registers, where N≥2. A shift register includes a control unit, an initial output unit and a first output unit. The control unit is configured to control a signal of the first output node and a signal of the second output node. The initial output unit is configured to at least receive the signal of the first output node and the signal of the second output node and control an initial output signal, the initial output signal of an x^{th} stage shift register is the input signal of a y^{th} stage shift register, 1≤x≤N, and 1≤y≤N. The first output unit is configured to at least receive the signal of the first output node and the signal of the second output node, and control a first output signal.

With the above-described technical solution, the shift register includes the control unit, the initial output unit and the first output unit, and in response to an input signal, the control unit may control the initial output unit to output an initial output signal and control the first output unit to output a first output signal, and the control unit may use the initial output signal of an x^{th} stage shift register as the input signal of a y^{th} stage shift register, the first output signal is taken as a control signal of pixel circuits in the display panel, so that the initial output signal provided to other stage shift register and the first output signal provided to the pixel circuits are independent from rom each other and do not affect each other, thereby flexibly controlling the polarity of the first output signal provided to the pixel circuit while ensuring that the cascading and shifting of signals can be performed among the shift registers, so that the drive modes of the pixel circuits of different rows in the display panel can be the same or different, thereby enabling the display panel to meet diversified display requirements, and widening the application scenario of the display panel.

The preceding is the core idea of the present disclosure. Based on the embodiments of the present disclosure, all other embodiments obtained by the person of ordinary skill in the art without creative work are within the scope of the present disclosure. Technical solutions in embodiments of the present disclosure are clearly and completely described in conjunction with drawings in the embodiments of the present disclosure.

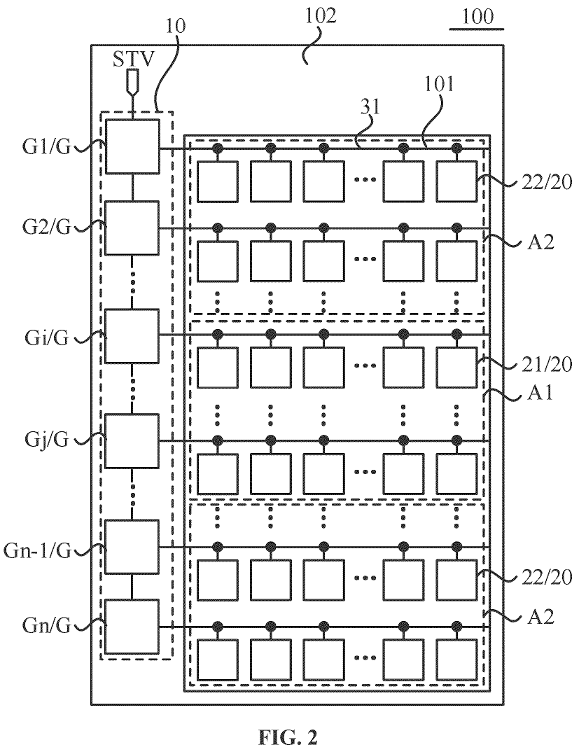

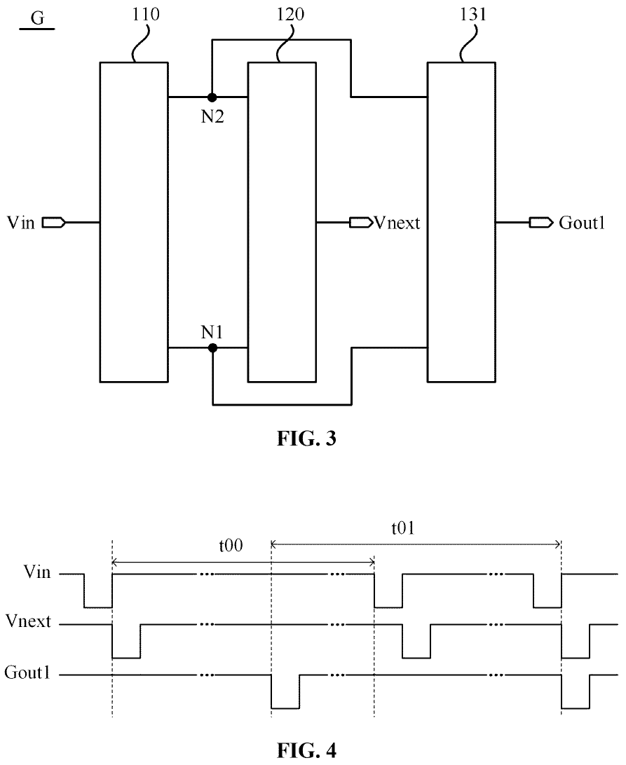

FIG. 2 is a schematic structural diagram of a display panel according to an embodiment of the present disclosure, and FIG. 3 is a schematic structural diagram of a shift register according to an embodiment of the present disclosure. Referring to FIG. 2 and FIG. 3, a display panel 100 includes a drive circuit 10. The drive circuit 10 includes N cascaded stages of shift registers G, where N≥2. A shift register G includes a control unit 110, an initial output unit 120 and a first output unit 131. The control unit 110 is configured to control a signal of a first output node N1 and a signal of a second output node N2, at least in response to an input signal Vin. The initial output unit 120 is configured to at least receive the signal of the first output node N1 and the signal of the second output node N2 and control an initial output signal Vnext. The first output unit 131 is configured to at least receive the signal of the first output node N1 and the signal of the second output node N2 and control a first output signal Gout1. The initial output signal of an x^{th} stage shift register Gx is the input signal of a y^{th} stage shift register Gy, 1≤x≤N, and 1≤y≤N.

The display panel 100 may include a display region 101 and a non-display region 102 surrounding the display region 101, the drive circuit 10 may be arranged in the non-display region 102, multiple pixel circuits 20 arranged in an array and multiple drive signal lines 31 may be arranged in the display region 101, and at least part of pixel circuits 20 located in the same row are electrically connected to the same drive signal line 31. In this case, output terminals of the first output units 131 of shift registers G of all stages may be electrically connected to different drive signal lines 31 respectively, to output the first output signals Gout1 to the drive signal lines respectively. In this manner, the drive signal lines 31 may transmit the first output signals Gout1 output by the first output units 131 of the N stages of shift registers G to the rows of pixel circuits 20, to drive the pixel circuits 20 in each row.

It is to be noted that the above only illustrates by taking it as an example that the drive circuit 10 is located in the non-display region 102 and the pixel circuits 20 are located in the display region 101, while in another embodiment of the present disclosure, the pixel circuits 20 and the drive circuit 10 may all be located at the display region 101, so that devices arranged in the non-display region 102 of the display panel 100 are less enough to reduce the dimension of the non-display region 102 in the display panel 100, thereby facilitating realization of narrow bezel of the display panel 100 and enabling the display panel 100 to have a higher screen-to-body ratio.

For the convenience of description, on the premise that no special limitation is imposed, in each of the embodiments of the present disclosure, the technical solution of the embodiment of the present disclosure is described by taking it as an example that the drive circuit is located at the non-display region of the display panel and the pixel circuits are located at the display region of the display panel.

With continued reference to FIG. 2 and FIG. 3, when the initial output signal of the x^{th} stage shift register Gx is the input signal of the y^{th} stage shift register Gy, the output terminal of the initial output unit 120 of the x^{th} stage shift register Gx may be electrically connected to the input terminal of the control unit 110 of the y^{th} stage shift register Gy. The x^{th} stage shift register Gx and the y^{th} stage shift register Gy may be two shift registers of adjacent stages, and in this case, if x is equal to i, y may be equal to x+1. Alternatively, the x^{th} stage shift register Gx and the y^{th} stage shift register Gy may be two shift registers of non-adjacent stages, and in this case, (x−y) may be any positive integer greater than or equal to 2. The values of x and y in the embodiments of the present disclosure are not limited, on the premise that the core inventive point of the embodiments of the present disclosure can be realized.

For the convenience of description, on the premise that no special limitation is imposed, the technical solution of the embodiment of the present disclosure is described in each embodiment of the present disclosure by taking the case that the x^{th} stage shift register and the y^{th} stage shift register are two adjacent stages of shift registers as an example.

Referring to FIG. 2 and FIG. 3, in the same shift register unit G, the control unit 110 may be electrically connected to the initial output unit 120 at the first output node N1 and the second output node N2, respectively, and the control unit 110 may further be electrically connected to the first output unit 131 at the first output node N1 and the second output node N2, respectively. For the first stage shift register G1, the input signal Vin received by the control unit 110 may be a start signal STV provided by a start control circuit (not shown), such that at least in response to the start signal STV, the first stage shift register G1 may provide corresponding signals to the first output node N1 and the second output node N2. For each stage of shift registers G other than the first stage shift register G1, the input terminal IN of the control unit 110 may be electrically connected to the output terminal of the initial output unit 120 of the previous stage shift register G, so that at least in response to the initial output signal Vnext output by the initial output unit 120 of the previous stage shift register G, each stage of shift register G can provide a corresponding signal to the first output node N1 and the second output node N2. In the same shift register G, the polarity of the signal of the first output node N1 and the polarity of the signal of the second output node N2 may be the same or opposite, and In one or more embodiments, for at least part of the time, the polarity of the signal of the first output node N1 and the polarity of the signal of the second output node N2 are opposite, that is, when the first output node N1 is a high level, the second output node N2 may be a low level, or when the first output node N1 is a low level, the second output node N2 may be a high level.

Accordingly, in the same shift register G, the initial output unit 120 may output a corresponding initial output signal Vnext according to the signal of the first output node N1 and the signal of the second output node N2 received by the initial output unit 120. At the same time, the first output unit 131 may output a corresponding first output signal Gout1 according to the signal of the first output node N1 and the signal of the second output node N2 received by the first output unit 131. The initial output signal Vnext and the first output signal Gout1 may each be a pulse signal composed of a high level and a low level.

Since the initial output signal Vnext and the first output signal Gout1 are respectively provided by the initial output unit 120 and the first output unit 131, and the structures and/or working modes of the initial output unit 120 and the first output unit 131 may be the same or different, the initial output signal Vnext and the first output signal Gout1 may be the same or different. For example, in some application scenarios, the voltage of the initial output signal Vnext may be different from the voltage of the first output signal Gout1, and/or, the frequency of the initial output signal Vnext may be different from the frequency of the first output signal Gout1. In some other application scenarios, the voltage and/or frequency of the initial output signal Vnext may be the same as that of the first output signal Gout1.

In one or more embodiments, FIG. 4 is a drive timing diagram of a shift register according to an embodiment of the present disclosure. Referring to FIG. 3 and FIG. 4, when the pulse change frequency of the initial output signal Vnext is F0 and the pulse change frequency of the first output signal Gout1 is F1, within at least a part of the time period of the working process of the display panel, F0≠F1.

In one or more embodiments, within at least a part of the time period of the working process of the display panel, the pulse change frequency F1 of the first output signal Gout1 is set to be different from the pulse change frequency F0 of the initial output signal Vnext, i.e., period t01 of the first output signal Gout1 is different from period t00 of the initial output signal Vnext. In this case, within a part of the time period of the working process of the display panel, the time of the effective pulse of the initial output signal Vnext overlaps the time of the inactive level of the first output signal Gout1, and/or, the time of the effective pulse of the first output signal Gout1 overlaps the time of the inactive level of the initial output signal Vnext, so that the time of the effective pulse of the initial output signal Vnext provided for the next stage shift register G does not overlap with the time of the effective pulse of the first output signal Gout1 provided to the pixel circuits. In this manner, the first output signal Gout1 and the initial output signal Vnext output by the same shift register G are independent of each other and do not affect each other, thereby meeting the driving requirements of the drive circuit while ensuring the normal display of the display panel.

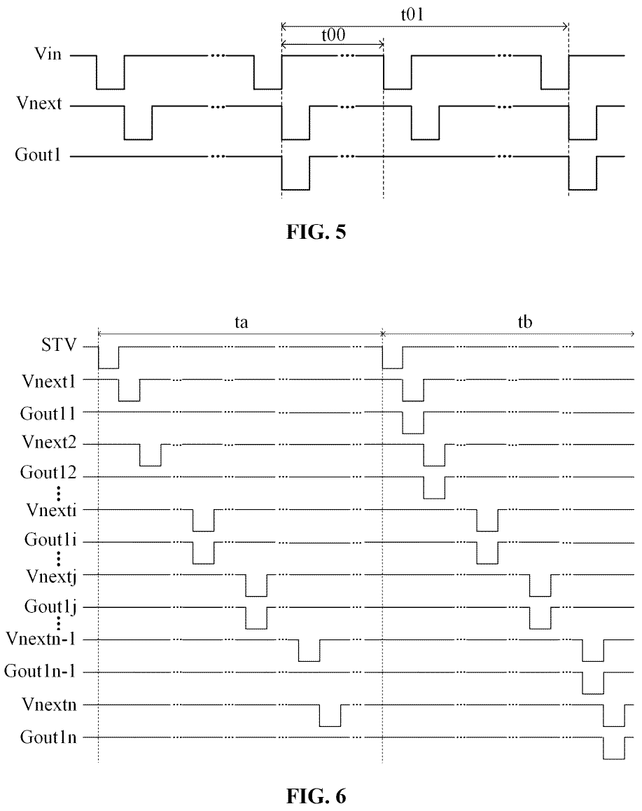

In one or more embodiments, FIG. 5 is a drive timing diagram of another shift register according to an embodiment of the present disclosure. Referring to FIG. 3 and FIG. 5, when the pulse change frequency of the initial output signal Vnext is F0 and the pulse change frequency of the first output signal Gout1 is F1, within at least a part of the time period of the working process of the display panel, F0>F1.

Within at least a part of the time period of the working process of the display panel, the pulse change frequency F0 of the initial output signal Vnext is set to be greater than the pulse change frequency F1 of the first output signal Gout1, i.e., period t01 of the first output signal Gout1 is greater than period t00 of the initial output signal Vnext, such that within a part of the time period of the working process of the display panel, the time of the effective pulse of the initial output signal Vnext overlaps the time of the inactive level of the first output signal Gout1, and within another part of the time period of the working process of the display panel, the time of the effective pulse of the first output signal Gout1 overlaps the time of the effective pulse of the initial output signal Vnext. As a result, within part of the time period, the initial output signal Vnext provided normally by the shift register G to the next stage shift register G includes an active level while the first output signal Gout1 provided normally by the shift register G to the pixel circuits is an inactive level, so that the next stage shift register G can work normally, and the pixel circuits may not perform signal refreshing. In the other part of the time period, the initial output signal Vnext provided by the shift register G to the next stage shift register G includes an active level while the first output signal Gout1 provided by the shift register G to the pixel circuits also includes an active level, so that the next stage shift register G can work normally and the pixel circuits can also perform signal refreshing. In this way, in a part of the time period, the power consumption caused by the signal refreshing of the pixel circuits can be reduced, thereby facilitating low power consumption of the display panel, while within another part of the time period, the signal in the pixel circuits is refreshed, thereby ensuring the normal display of the display panel and preventing the flicker of the image.

In one or more embodiments, when the pulse change frequency F0 of the initial output signal Vnext is greater than the pulse change frequency F1 of the first output signal Gout1, the pulse change frequency F0 of the initial output signal Vnext may be an integer multiple of the pulse change frequency F1 of the first output signal Gout1, for example, F0 may be equal to 2*F1 or 3*F1, or the like. In another embodiment, the pulse change frequency F0 of the initial output signal Vnext may also be a non-integer multiple of the pulse change frequency F1 of the first output signal Gout1, for example, F0 may be equal to 3/2*F1 or 12/5*F1, or the like. The relationship between F0 and F1 is not limited in the embodiments of the present disclosure.

It may be understood that when the drive circuit of the display panel includes multiple stages of shift register G, the pulse change frequency F0 of the initial output signal Vnext of each stage shift register G may be greater than the pulse change frequency F1 of the first output signal Gout1, in this case, the drive frequency of the drive circuit may be greater than the signal refresh rate of each pixel circuit. Alternatively, it is possible that only a part of the shift registers G have the pulse change frequency F0 of the initial output signal Vnext greater than the pulse change frequency F1 of the first output signal Gout1 thereof, while for another part of the shift registers G, the pulse change frequency F0 of the initial output signal Vnext may be less than or equal to the pulse change frequency F1 of the first output signal Gout1 thereof, which is not limited in the embodiments of the present disclosure as long as the diversified display requirements of the display panel can be met.

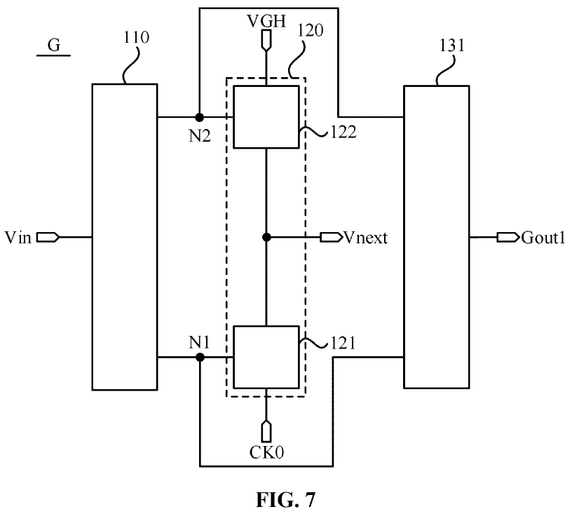

In an exemplary embodiment, FIG. 6 is a drive timing diagram of a drive circuit according to an embodiment of the present disclosure. With reference to FIG. 2, FIG. 3 and FIG. 6, the display panel 100 may include a first display region A1 and a second display region A2. Pixel circuits 20 in the first row to an (i−1)^{th} row and a (j+1)^{th} row to an n^{th} row are second pixel circuits 22, pixel circuits 20 in an i^{th} row to a j^{th} row are first pixel circuits 21, the first pixel circuits 21 are located in the first display region A1, and the second pixel circuits 22 are located in the second display region A2. In this case, if the pulse change frequency of the first output signals (Gout1i, . . . , Gout1j) provided to the first pixel circuits 21 is Fc10, and the pulse change frequency of the first output signals (Gout11, Gout12, . . . , Gout1i−1, Gout1j+1, . . . , Gout1n−1, Gout1n) provided to the second pixel circuits 22 is Fc20, it may be Fc10>Fc20, such that the pulse change frequency of the initial output signals (Vnext1, Vnext2, . . . , Vnexti−1, Vnextj+1, . . . , Vnextn−1, Vnextn) output by the first stage shift register G1 to an (i−1)^{th} stage shift register Gi−1 and a (j+1)^{th} stage shift register Gj+1 to an n^{th} stage shift register Gn is greater than the pulse change frequency of the first output signals (Gout11, Gout12, . . . , Gout1i−1, Gout1j+1, . . . , Gout1n−1, Gout1n) output by the first stage shift register G1 to the (i−1)^{th} stage shift register Gi−1 and the (j+1)^{th} stage shift register Gj+1 to the n^{th} stage shift register Gn, while the pulse change frequency of the initial output signals (Vnexti, . . . , Vnextj) output by an i^{th} stage shift register Gi to a j^{th} stage shift register Gj may be equal to the pulse change frequency F11 of the first output signals (Gout1i, . . . , Gout1j) output by the i^{th} stage shift register Gi to the j^{th} stage shift register Gj. In this way, in the time period ta, the time of the effective pulse of the initial output signal (Vnext1, Vnext2, . . . , Vnexti, Vnextj, . . . , Vnextn−1, Vnextn) output by each stage of shift register G shifts sequentially, also the time of the effective pulse of the first output signal (Gout1i, . . . , Gout1j) output sequentially by the i^{th} stage shift register to the j^{th} stage shift register shifts sequentially, and the first output signals (Gout11, Gout12, . . . , Gout1i-1, Gout1j+1, . . . , Gout1n-1, Gout1n) output by the first stage shift register G1 to the (i−1)^{th} stage shift register Gi−1 and the (j+1)^{th} stage shift register Gj+1 to the n^{th} stage shift register Gn are maintained as an inactive level. In the time period tb, both the time of the effective pulse of the initial output signal (Vnext1, Vnext2, . . . , Vnexti, Vnextj, . . . , Vnextn−1, Vnextn) and the time of the effective pulse of the first output signals (Gout11, Gout12, . . . , Gout1i, Gout1j, . . . , Gout1n−1, Gout1n) output by the shift registers G of all stages shift sequentially, so that in the time period ta, the first pixel circuits 21 can perform signal refreshing and the second pixel circuits 22 fail to perform signal refreshing, while in the time period tb, all the pixel circuits 20 can perform the signal refreshing, thereby ensuring that the first pixel circuits 21 in the first pixel display region A1 have a higher signal refresh rate, while the second pixel circuits 22 in the second pixel display region A2 have a lower signal refresh rate. In this manner, it can be ensured that the display panel 100 has a better display effect and the low power consumption of the display panel 100 can be facilitated, thus, the display panel 100 can be applicable to different application scenarios.

It may be appreciated that the above only provides an exemplary explanation with the first display region A1 located between two second display regions A2 as an example, while in the embodiments of the present disclosure, the first display region and the second display region may be designed according to practical display requirements. For example, when the display panel is in a static standby image for displaying only the time, the image at the time display region changes in real time, and it is required to refresh the pixel circuits at the time display region in real time, ensuring that the region can accurately display the time. The image in the other region remains unchanged, it is not required to refresh the pixel circuits in those regions in real time. In this case, the refresh rate of the time display region may be greater than the refresh rate of the other region, that is, the time display region is the first display region while the other region is the second display region.

In this embodiment, the initial output signal output by the initial output unit is used as the input signal of a shift register of another stage, and the first output signal output by the first output unit is used as the drive signal of the pixel circuits in the display panel, so that the initial output signal provided to the shift register of another stage and the first output signal provided to the pixel circuits are independent of each other and do not affect each other, thus the polarity of the first output signal provided to the pixel circuits can be flexibly controlled while the cascaded transmission and shifting of signals between the shift registers can be ensured. In this manner, the drive modes of the pixel circuits in different rows of the display panel can be the same or different, thereby enabling the display panel to meet multiple display requirements, and widening the application scenario of the display panel, for example, different regions of the display panel can have different refresh rates.

It is to be noted that since both the initial output unit and the first output unit receive at least the signals of the first output node and the second output node, the signals of the first output node and the second output node can control the initial output signal output by the initial output unit and control the first output signal output by the first output unit, and the initial output signal and the first output signal may be the same or different, which is related to the structures of the initial output unit and the first output unit, and the structures of the initial output unit and the first output unit are described for example below by typical examples.

In one or more embodiments, FIG. 7 is a schematic structural diagram of another shift register according to an embodiment of the present disclosure. As illustrated in FIG. 7, the initial output unit 120 includes a first initial output module 121 and a second initial output module 122. The first initial output module 121 at least receives an initial output control signal CK0 and the signal of the first output node N1, and controls an initial output signal Vnext. The second initial output module 122 at least receives a first voltage signal VGH and the signal of the second output node N2, and controls the initial output signal Vnext.

The first initial output module 121 at least receives the initial output control signal CK0 and the signal of the first output node N1 so that the first initial output module 121 can output the initial output signal Vnext under the control of the initial output control signal CK0 and the signal of the first output node N1. The second initial output module 122 at least receives the first voltage signal VGH and the signal of the second output node N2 so that the second initial output module 122 can output the initial output signal Vnext under the control of the first voltage signal VGH and the signal of the second output node N2. In this case, the first output node N1, the second output node N2, the first voltage signal VGH and the initial output control signal CK0 can determine the polarity and amplitude of the initial output signal Vnext.

In an exemplary embodiment, when the signal of the first output node N1 is an active level, the first initial output module 121 may control the initial output signal Vnext to be consistent with the initial output control signal CK0, while when the signal of the second output node N2 is an active level, the second initial output module 122 may control the initial output signal Vnext to be consistent with the first voltage signal VGH.

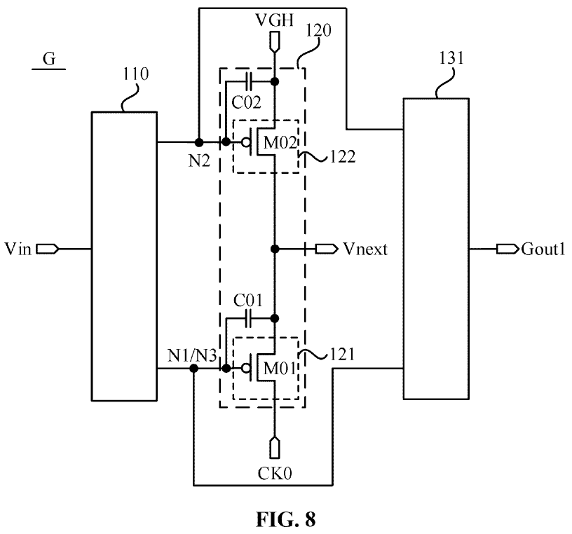

FIG. 8 is a schematic structural diagram of another shift register according to an embodiment of the present disclosure. As shown in FIG. 8, the first initial output module 121 includes a first initial output transistor M01. A first electrode of the first initial output transistor M01 is configured to receive the initial output control signal CK0, a second electrode of the first initial output transistor M01 is configured to output the initial output signal Vnext, a gate of the first initial output transistor M01 is connected to the first output node N1 or a third output node N3, and the first output node N1 may be directly connected to the third output node N3, that is, the signal of the first output node N1 and the signal of the third output node N3 are the same. As such, the first initial output transistor M01 may be turned on or off under the control of the signal of the first output node N1. When the signal of the first output node N1 controls the first initial output transistor M01 to be turned on, the initial output control signal CK0 received by the first electrode of the first initial output transistor M01 is transmitted to the second electrode of the first initial output transistor M01 so that the initial output control signal CK0 serves as the initial output signal Vnext output by the second electrode of the first initial output transistor M01.

Accordingly, with continued reference to FIG. 8, the second initial output module 122 may include a second initial output transistor M02. A first electrode of the second initial output transistor M02 is configured to receive the first voltage signal VGH, a second electrode of the second initial output transistor M02 is configured to output the initial output signal Vnext, and a gate of the second initial output transistor M02 is connected to the second output node N2. As such, the second initial output transistor M02 may be turned on or off under the control of the signal of the second output node N2. When the signal of the second output node N2 controls the second initial output transistor M02 to be turned on, the first voltage signal VGH received by the first electrode of the second initial output transistor M02 is transmitted to the second electrode of the second initial output transistor M02 so that the first voltage signal VGH serves as the initial output signal Vnext output by the second electrode of the second initial output transistor M02.

The initial output control signal CK0 may be a pulse signal at a frequency of Fc0 such that the initial output control signal CK0 includes a high level and a low level. The first voltage signal VGH is a fixed signal, for example, the first voltage signal VGH may be a high-level signal so that when it is required to output a high-level initial output signal Vnext, the first output node N1 controls the first initial output transistor M01 to be turned on when the initial output control signal CK0 is a high level, and/or, the second output node N2 controls the second initial output transistor M02 to be turned on, so that the initial output signal Vnext is consistent with the high-level initial output control signal CK0 and/or the first voltage signal VGH. When it is required to output a low-level initial output signal Vnext, the first output node N1 controls the first initial output transistor M01 to be turned on when the initial output control signal CK0 is a low level so that the initial output signal Vnext is consistent with the low-level initial output control signal CK0. With this arrangement, the initial output signal Vnext can be a pulse signal having a high level and a low level, thereby meeting the driving requirements of the shift registers G.

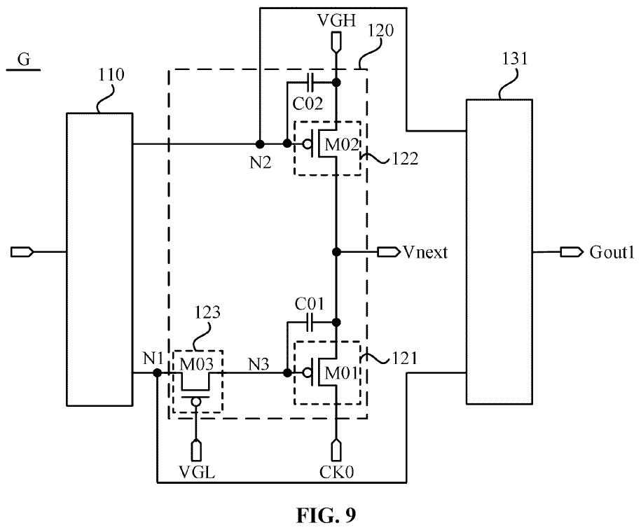

In another embodiment, FIG. 9 is a schematic structural diagram of another shift register according to an embodiment of the present disclosure. As shown in FIG. 9, the initial output unit 120 may further include an initial stabilization module 123. In this case, the first output node N1 is connected to the third output node N3 through the initial stabilization module 123, that is, the first output node N1 and the third output node N3 are different nodes. The initial stabilization module 123 can isolate the gate of the first initial output transistor M01 from the first output node N1 to ensure that the signal of the first output node N1 and the signal of the third output node N3 are relatively stable, and the fluctuations of the signal of the first output node N1 and/or the signal of the third output node N3 can be prevented from adversely affecting the accuracy of the initial output signal Vnext output by the first initial output transistor M01, thereby facilitating the improvement of the working stability of the shift registers G and further facilitating the improvement of the display effect of the display panel.

In one or more embodiments, the initial stabilization module 123 may include a third initial output transistor M03. A first electrode of the third initial output transistor M03 is connected to the first output node N1, a second electrode of the third initial output transistor M03 is connected to the third output node N3, and a gate of the third initial output transistor M03 receives a second voltage signal VGL.

The second voltage signal VGL may control the third initial output transistor M03 to remain the on state continuously, such that the signal of the first output node N1 remains substantially consistent with the signal of the third output node N3. However, since the turned-on third initial output transistor M03 has a certain resistance, when the signal of the third output node N3 electrically connected to the first initial output transistor M01 changes, the third initial output transistor M03 can reduce the change amount at which the signal of the first output node N1 changes with the signal of the third output node N3. Similarly, when the signal of the first output node N1 changes, the third initial output transistor M03 can also reduce the change amount at which the signal of the third output node N3 changes with the signal of the first output node N1. Thus, by providing the third initial output transistor M03 between the first output node N1 and the third output node N3, the stability of the signals at the first output node N1 and the third output node N3 can be ensured, thereby improving the stability of the initial output signal Vnext output by the first initial output transistor M01.

It may be appreciated that the first initial output transistor M01, the second initial output transistor M02, and the third initial output transistor M03 may each be an N-type transistor or a P-type transistor. For the N-type transistor, when the signal received by the gate of the transistor is a high level, the transistor is turned on, and when the signal received by the gate is a low level, the transistor is turned off. For the P-type transistor, when the signal received by the gate of the transistor is a low level, the transistor is turned on, and when the signal received by the gate is a high level, the transistor is turned off. The high level and low level of the signal at the gate of the transistor are defined relative to the signal at the source of the transistor, the amplitudes and polarities of the high level and low level of the signal are not limited in the embodiments of the present disclosure. Therefore, for transistors of different types, to realize the same technical principle, it is simply required to adaptively adjust the signal at the gate of the transistor according to the type of the transistor. For the convenience of the description, on the premise that no special limitations are imposed, each embodiment of the present disclosure takes the referred transistor being a P-type transistor as an example, to illustrate the technical solutions of the embodiments of the present disclosure.

In one or more embodiments, when the second voltage signal VGL is a low-level signal, the low-level second voltage signal VGL can control the third initial transistor M03 to be in the on state, such that the signal of the first output node N1 remains substantially consistent with the signal of the third output node N3.

On the basis of the above-described embodiments, the initial output unit 120 may further include an initial bootstrap capacitor C01, the initial bootstrap capacitor C01 may be electrically connected between the second electrode of the first initial output transistor M01 and the gate of the first initial output transistor M01, so that when the initial output signal Vnext at the second electrode of the first initial output transistor M01 hops from the high level to the low level or from the low level to the high level, the signal at the gate of the first initial output transistor M01 may be controlled to change with the initial output signal Vnext due to the coupling of the initial bootstrap capacitor C01, thereby ensuring that the signal at the gate of the first initial output transistor M01 has sufficiently high drive capability to drive the first initial output transistor M01 to be turned on or off.

Furthermore, the initial output unit 120 may further include a hold capacitor C02, a first plate of the hold capacitor C02 receives the first voltage signal VGH, a second plate of the hold capacitor C02 is electrically connected to the second output node N2, so that the hold capacitor C02 stores the signal of the second output node N2 to ensure that the signal of the second output node N2 can continuously control the second initial output transistor M02 to be turned on or off.

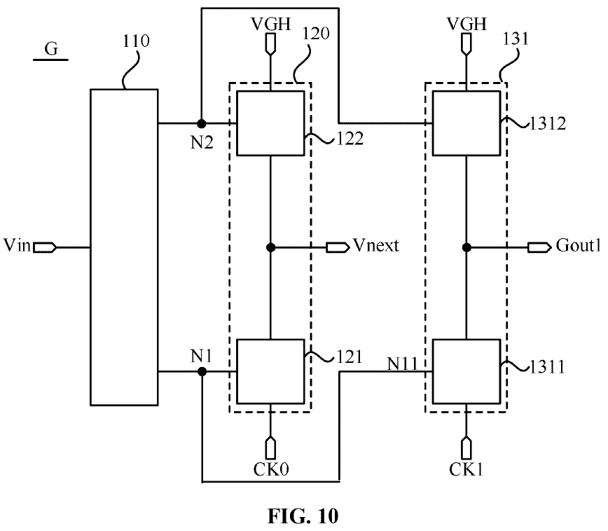

Alternatively, FIG. 10 is a schematic structural diagram of another shift register according to an embodiment of the present disclosure. As illustrated in FIG. 10, the first output unit 131 may include a first output module 1311 and a second output module 1312. The first output module 1311 at least receives a first output control signal CK1 and the signal of the first output node N1, and controls a first output signal Gout1. The second output module 1312 at least receives the first voltage signal VGH and the signal of the second output node N2, and controls the first output signal Gout1.

The first output module 1311 at least receives the first output control signal CK1 and the signal of the first output node N1 so that the first output module 1311 outputs the first output signal Gout1 under the control of the first output control signal CK1 and the signal of the first output node N1. The second output module 1312 at least receives the first voltage signal VGH and the signal of the second output node N2 so that the second output module 1312 outputs the first output signal Gout1 under the control of the first voltage signal VGH and the signal of the second output node N2. In this case, the first output node N1, the second output node N2, the first voltage signal VGH and the first output control signal CK1 can determine the polarity and amplitude of the first output signal Gout1.

In an exemplary embodiment, when the signal of the first output node N1 is an active level, the first output module 1311 may control the first output signal Gout1 to be consistent with the first output control signal CK1, while when the signal of the second output node N2 is an active level, the second output module 1312 may control the first output signal Gout1 to be consistent with the first voltage signal VGH.

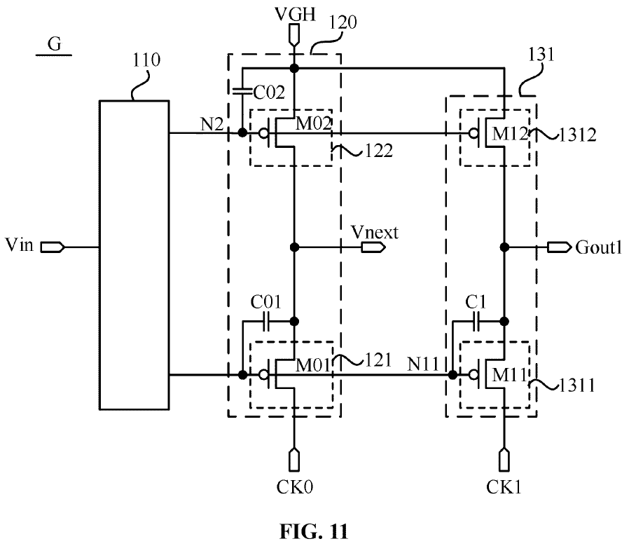

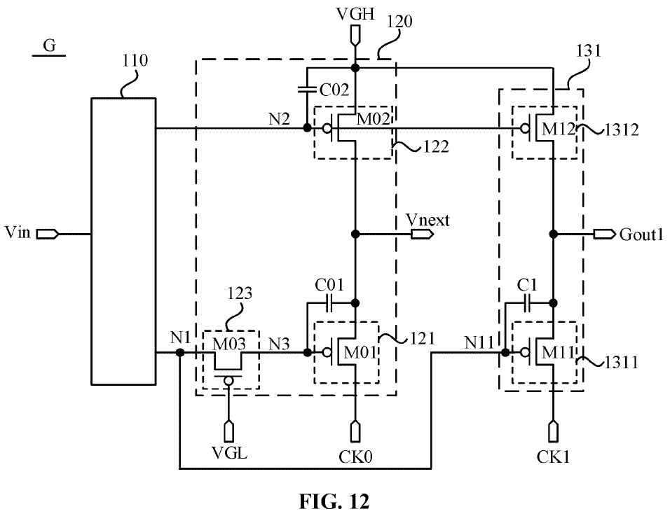

Alternatively, FIG. 11 is a schematic structural diagram of another shift register according to an embodiment of the present disclosure. FIG. 12 is a schematic structural diagram of another shift register according to an embodiment of the present disclosure. With reference to any one of FIG. 11 and FIG. 12, the first output module 1311 includes a first transistor M11. A first electrode of the first transistor M11 is configured to receive the first output control signal CK1, a second electrode of the first transistor M11 is configured to output the first output signal Gout1, and a gate of the first transistor M11 is connected to the first output node N1 or a first node N11. The first output node N1 is directly connected to the first node N11, that is, the signal of the first output node N1 and the signal of the first node N11 are the same. As such, the first transistor M11 may be turned on or off under the control of the signal of the first output node N1, and when the signal of the first output node N1 controls the first transistor M11 to be turned on, the first output control signal CK1 received by the first electrode of the first transistor M11 is transmitted to the second electrode of the first transistor M11 such that the first output control signal CK1 serves as the first output signal Gout1 output by the second electrode of the first transistor M11.

Accordingly, with continued reference to any one of FIG. 11 and FIG. 12, the second output module 1312 includes a second transistor M12. A first electrode of the second transistor M12 is configured to receive the first voltage signal VGH, a second electrode of the second transistor M12 is configured to output the first output signal Gout1, and a gate of the second transistor M12 is connected to the second output node N2. As such, the second transistor M12 may be turned on or off under the control of the signal of the second output node N2, and when the signal of the second output node N2 controls the second transistor M12 to be turned on, the first voltage signal VGH received by the first electrode of the second transistor M12 is transmitted to the second electrode of the second transistor M12 such that the first voltage signal VGH serves as the first output signal Gout1 output by the second electrode of the second transistor M12.

The first output control signal CK1 may be a pulse signal with a pulse change frequency of Fc1 such that the first output control signal CK1 includes a high level and a low level. The first voltage signal VGH is a fixed signal, for example, the first voltage signal VGH may be a high-level signal, so that when it is required to output a high-level first output signal Gout1, the first output node N1 controls the first transistor M11 to be turned on when the first output control signal CK1 is a high level, and/or, the second output node N2 controls the second transistor M12 to be turned on, so that the first output signal Gout1 is kept consistent with the high-level first output control signal CK1 and/or the first voltage signal VGH. When it is required to output a low-level first output signal Gout1, the first output node N1 controls the first transistor M11 to be turned on when the first output control signal CK1 is a low level, to enable the first output signal Gout1 to be consistent with the low-level first output control signal CK1. With this arrangement, the first output signal Gout1 can be a pulse signal having a high level and a low level, thereby meeting the driving requirements of the shift registers G.

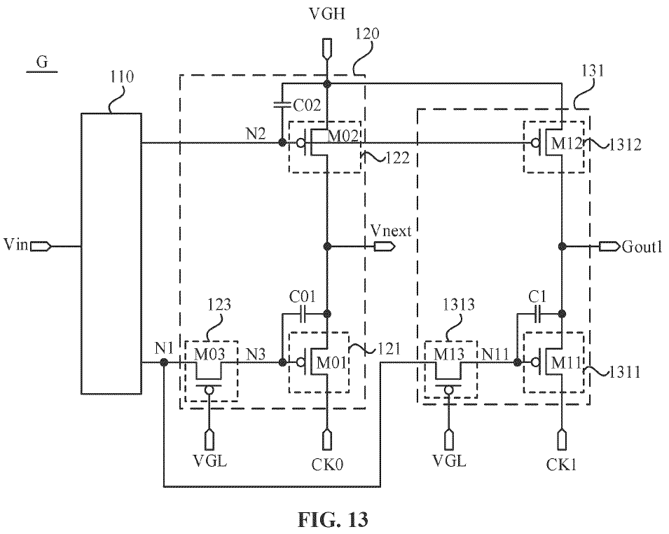

In another embodiment, FIG. 13 is a schematic structural diagram of another shift register according to an embodiment of the present disclosure. As shown in FIG. 13, the first output unit 131 may further include a first stabilization module 1313. In this case, the first output node N1 is connected to the first node N11 through the first stabilization module 1313, that is, the first output node N1 and the first node N11 are different nodes, and the first stabilization module 1313 can isolate the first output node N1 from the first node N11 to ensure that the signal of the first output node N1 and the signal of the first node N11 are relatively stable, and to prevent the fluctuation of the signals of the first output node N1 and/or the first node N11 from adversely affecting the accuracy of the first output signal Gout1 output by the first transistor M11, thereby facilitating the improvement of the working stability of the shift registers G and further facilitating the improvement of the display effect of the display panel.

In one or more embodiments, with continued reference to FIG. 13, the first stabilization module 1313 may include a third transistor M13. A first electrode of the third transistor M13 is connected to the first output node N1, a second electrode of the third transistor M13 is connected to the first node N11, and a gate of the third transistor M13 receives the second voltage signal VGL.

The second voltage signal VGL may control the third transistor M13 to remain the on state continuously, such that the signal of the first output node N1 is substantially consistent with the signal of the first node N11. However, since the turned-on third transistor M13 has a certain resistance, when the signal of the first node N11 electrically connected to the first transistor M11 changes, the third transistor M13 can reduce the change amount at which the signal of the first output node N1 changes with the signal of the first node N11; similarly, when the signal of the first output node N1 changes, the third transistor M13 can also reduce the change amount at which the signal of the first node N11 changes with the signal of the first output node N1. Thus, by arranging the third transistor M13 between the first output node N1 and the first node N11, the stability of the signals at the first output node N1 and the first node N11 can be ensured, thereby the stability of the first output signal Gout1 output by the first transistor M11 is improved.

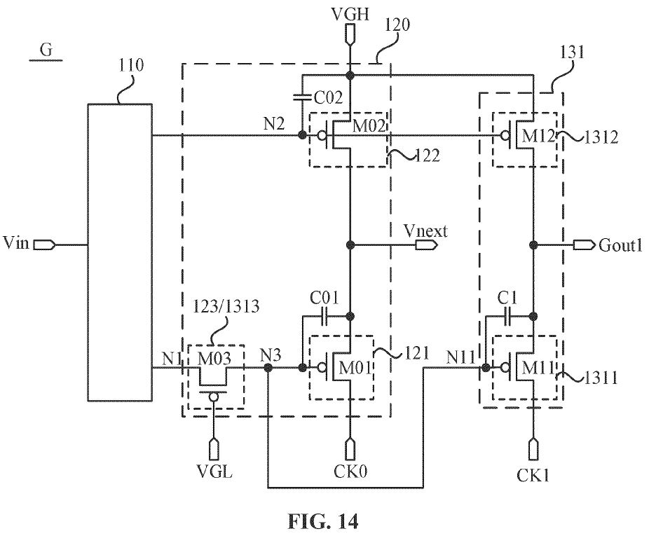

In other embodiments, as shown in FIG. 14, when the initial output unit further includes an initial stabilization module 123, the initial stabilization module 123 may also be used as the first stabilization module 1313, in this case, the first node N11 is directly electrically connected to the third output node N3, and the first node N11 may be connected to the first output node N1 through the initial stabilization module 123, so that the initial stabilization module 123 can further be configured to stabilize the signal of the first node N11. In this way, the structure of the shift registers G can be simplified, thereby facilitating the reduction in the dimension of the shift registers G and further facilitating the realization of the narrow bezel of the display panel.

On the basis of the above-described embodiments, with reference to any one of FIG. 11 to FIG. 14, the first output unit 131 may further include a first bootstrap capacitor C1, the first bootstrap capacitor C1 may be electrically connected between the second electrode of the first transistor M11 and the gate of the first transistor M11, so that when the first output signal Gout1 at the second electrode of the first transistor M11 hops from the high level to the low level or from the low level to the high level, the signal at the gate of the first transistor M11 may be controlled to change with the first output signal Gout1 due to the coupling of the first bootstrap capacitor C1, thereby ensuring that the signal at the gate of the first transistor M11 has a sufficiently high drive capability to drive the first transistor M11 to be turned on or off.

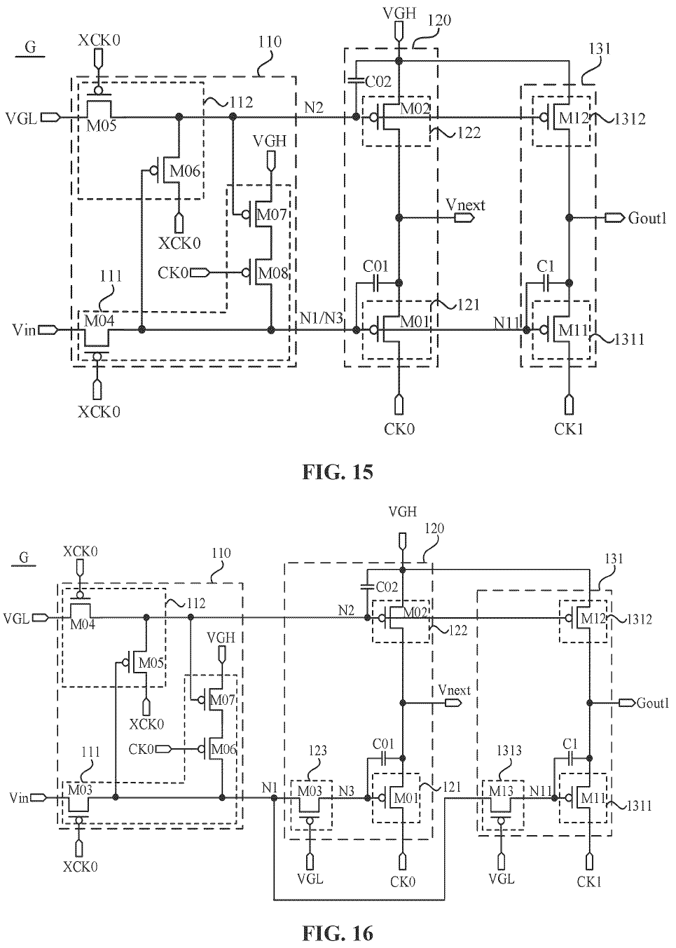

On the basis of the above embodiment, FIG. 15 is a schematic structural diagram of another shift register according to an embodiment of the present disclosure. FIG. 16 is a schematic structural diagram of another shift register according to an embodiment of the present disclosure. Referring to FIG. 15 or FIG. 16, the control unit 110 may include a first control module 111 and a second control module 112. The first control module 111 may at least receive the first voltage signal VGH, the input signal Vin, the initial output control signal CK0 and a first clock signal XCK0, and control the signal of the first output node N1. The second control module 112 may at least receive the second voltage signal VGL and the first clock signal XCK0 and control the signal of the second output node N2.

The first control module 111 may provide a signal for the first output node N1 under the control of the first voltage signal VGH, the first clock signal XCK0, the initial output control signal CK0 and the input signal Vin such that the first voltage signal VGH, the first clock signal XCK0, the initial output control signal CK0 and the input signal Vin can control the polarity and amplitude of the signal of the first output node N1. The second control module 112 may provide a signal for the second output node N2 under the control of the second voltage signal VGL and the first clock signal XCK0 such that the second voltage signal VGL and the first clock signal XCK0 can control the polarity and amplitude of the signal of the second output node N2.

In an exemplary embodiment, when the first clock signal XCK0 is an active level, the first control module 111 may transmit the input signal Vin to the first output node N1 so that the signal of the first output node N1 is consistent with the input signal Vin, and the second control module 112 may transmit the second voltage signal VGL to the second output node N2 so that the signal of the second output node N2 is consistent with the second voltage signal VGL.

In one or more embodiments, the first control module 111 may include a first control transistor M04, a second control transistor M07 and a third control transistor M08. A first electrode of the first control transistor M04 receives the input signal Vin, a second electrode of the first control transistor M04 is electrically connected to the first output node N1, and a gate of the first control transistor M04 receives the first clock signal XCK0. A first electrode of the second control transistor M07 receives the first voltage signal VGH, a second electrode of the second control transistor M07 is electrically connected to the first electrode of the third control transistor M08, a second electrode of the third control transistor M08 is electrically connected to the first output node N1, a gate of the second control transistor M07 is electrically connected to the second output node N2, and a gate of the third control transistor M08 receives the initial output control signal CK0. In this case, the first clock signal XCK0 can control the first control transistor M04 to be turned on or off, and when the first clock signal XCK0 controls the first control transistor M04 to be turned on, the first control transistor M04 can transmit the input signal Vin to the first output node N1 so that the signal of the first output node N1 is consistent with the input signal Vin. The signal of the second output node N2 can control the second control transistor M07 to be turned on or off, and the initial output control signal CK0 can control the third control transistor M08 to be turned on or off, and when the signal of the second output node N2 controls the second control transistor M07 to be turned on and the initial output control signal CK0 controls the third control transistor M08 to be turned on, the first voltage signal VGH is transmitted to the first output node N1 such that the signal of the first output node N1 keeps consistent with the first voltage signal VGH.

Accordingly, the second control module 112 may include a fourth control transistor M05 and a fifth control transistor M06. A first electrode of the fourth control transistor M05 receives the second voltage signal VGL, a second electrode of the fourth control transistor M05 is electrically connected to the second output node N2, and a gate of the fourth control transistor M05 receives the first clock signal XCK0. A first electrode of the fifth control transistor M06 receives the first clock signal XCK0, a second electrode of the fifth control transistor M06 is electrically connected to the second output node N2, and a gate of the fifth control transistor M06 is electrically connected to the first output node N1. In this case, the first clock signal XCK0 may control the fourth control transistor M05 to be turned on or off, and the signal of the first output node N1 controls the fifth control transistor M06 to be turned on or off. When the first clock signal XCK0 controls the fourth control transistor M05 to be turned on, the fourth control transistor M05 can transmit the second voltage signal VGL to the second output node N2, so that the signal of the second output node N2 keeps consistent with the second voltage signal VGL. When the signal of the first output node N1 controls the fifth control transistor M06 to be turned on, the signal of the second output node N2 keeps consistent with the first clock signal XCK0.

It may be appreciated that the first clock signal XCK0 may be a pulse signal such that the first clock signal XCK0 may include a high level and a low level. The input signal Vin is the initial output signal Vnext of the previous stage shift register G so that the input signal Vin may likewise include a high level and a low level. The first voltage signal VGH and the second voltage signal VGL are fixed signals, for example, the second voltage signal VGL may be a low-level signal, and the first voltage signal VGH may be a high-level signal. The pulse change frequency of the first clock signal XCK0 and the pulse change frequency of the initial output control signal CK0 may be the same, that is, the pulse change frequencies of the first clock signal XCK0 and the initial output control signal CK0 are both Fc0. In this case, the phase of the first clock signal XCK0 is different from the phase of the initial output control signal CK0, that is, when the first clock signal XCK0 is an active level, the initial output control signal CK0 is an inactive level; and in contrast, when the initial output control signal CK0 is an active level, the first clock signal XCK0 is an inactive level.

When the second output node N2 requires a low-level signal, the first clock signal XCK0 may be enabled to control the fourth control transistor M05 to be turned on, thus, the low-level first voltage signal VGL may be transmitted to the second output node N2 through the turned-on fourth control transistor M05, and/or, when the first clock signal XCK0 is a low level, the signal of the first output node N1 controls the fifth control transistor M06 to be turned on, so that the low-level first clock signal XCK0 is transmitted to the second output node N2. When the second output node N2 requires a high-level signal, the fifth control transistor M06 may be controlled to be turned on by the signal of the first output node N1 when the first clock signal XCK0 is a high level, so that the high-level first clock signal XCK0 is transmitted to the second output node N2, thereby, the signal of the second output node N2 may be set according to practical requirements.

Similarly, when the first output node N1 requires a high-level signal, the first clock signal XCK0 may control the first control transistor M04 to be turned on when the input signal Vin is a high level, and at this time, the signal of the first output node N1 can be consistent with the high-level input signal Vin, or while the signal of the second output node N2 controls the second control transistor M07 to be turned on, the initial output control signal CK0 controls the third control transistor M08 to be turned on, so that the high-level first voltage signal VGH is transmitted to the first output node N1. When the first output node N1 requires a low-level signal, the first clock signal XCK0 may be enabled to control the first control transistor M04 to be turned on when the input signal Vin is a low level, so that the first control transistor M04 can transmit the low-level input signal Vin to the first output node N1. With this arrangement, the signal of the first output node N1 can be controlled as required.

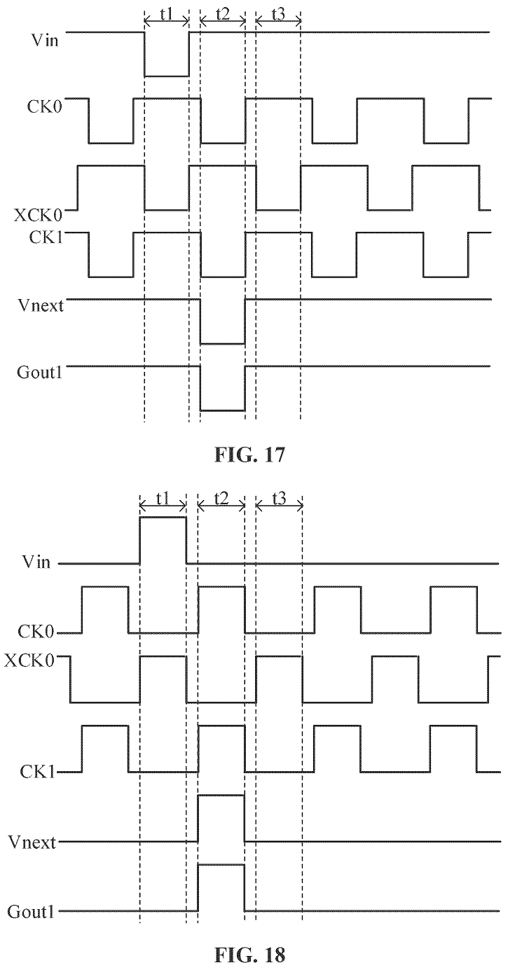

In an exemplary embodiment, the case that each transistor in the shift register is a p-type transistor is taken as an example. FIG. 17 is a drive timing diagram of a shift register according to an embodiment of the present disclosure. Referring to FIG. 15 and FIG. 17, before t1 stage, since the input signal Vin is a high level, when the first clock signal XCK0 controls the first control transistor M04 to be turned on, the first control transistor M04 may transmit the high-level input signal Vin to the first output node N1, so that the signal of the first output node N1 is a high level. When the signal of the second output node N2 controls the second control transistor M07 to be turned on and the initial output control signal CK0 controls the third control transistor M08 to be turned on, the high-level first voltage signal VGH is transmitted to the first output node N1, which also enables the signal of the first output node N1 to be a high level, so that the signal of the first output node N1 controls both the first initial output transistor M01 and the first transistor M11 to be the off state. Since the second voltage signal VGL is a low level, when the first clock signal XCK0 controls the fourth control transistor M05 to be turned on, the low-level second voltage signal VGL may be transmitted to the second output node N2. In addition, since the first output node N1 is a high level, the fifth control transistor M06 may keep the off state, and the hop of the first clock signal XCK0 will not affect the signal of the second output node N2, so that the signal of the second output node N2 keeps the low-level signal, and the signal of the second output node N2 can control the second initial output transistor M02 and the second transistor M12 to be in the on state, so that the initial output signal Vnext and the first output signal Gout1 are both consistent with the first voltage signal VGH, that is, the initial output signal Vnext and the first output signal Gout1 are both the high level.

At phase t1, when the input signal Vin is turned to a low level, the first clock signal XCK0 is a low level at the same time, and the initial output control signal CK0 and the first output control signal CK1 are both the high level. In this case, the first clock signal XCK0 controls both the first control transistor M04 and the fourth control transistor M05 to be turned on, and the low-level input signal Vin may be transmitted to the first output node N1 through the first control transistor M04, so that the signal of the first output node N1 is turned to a low level. This low-level signal can control both the first initial output transistor M01 and the first transistor M11 to be turned on, so that the initial output control signal CK0 is transmitted to the second electrode of the first initial output transistor M01, and the first output control signal CK1 is transmitted to the second electrode of the first transistor M11. Meanwhile, the second voltage signal VGL is also transmitted to the second output node N2 through the fourth control transistor M05 so that the second output node N2 is also a low level, and the low-level signal can control the second initial output transistor M02 and the second transistor M12 to be turned on at the same time, so that the high-level first voltage signal VGH is transmitted to the second electrode of the second initial output transistor M02, and the first voltage signal VGH may further be transmitted to the second electrode of the second transistor M12. In this case, the signal at the second electrode of the first initial output transistor M01 and the signal at the second electrode of the second initial output transistor M02 are both high-level signals so that the initial output signal Vnext is kept at the high level, and the signal at the second electrode of the first transistor M11 and the signal at the second electrode of the second transistor M12 are both the high-level signals so that the first output signal Gout1 is also kept at the high level. Furthermore, since the signal of the first output node N1 is the low level, the fifth control transistor M06 is in the on state, the low-level first clock signal XCK0 is transmitted to the second output node N2 through the fifth control transistor M06, so that the second output node N2 keeps a low level; at the same time, since the signal of the second output node N2 is a low level, the second control transistor M07 is in the on state, but because the initial output control signal CK0 is a high level, the third control transistor M08 is in the off state, the first voltage signal VGH cannot be transmitted to the first output node N1, and the signal of the first output node N1 is kept consistent only with the input signal Vin.

At phase t2, the input signal Vin is turned to a high level, and the first clock signal XCK0 is also the high level. The initial output control signal CK0 and the first output control signal CK1 are the low level. The first clock signal XCK0 controls both the first control transistor M04 and the second control transistor M07 to be turned off, and the first output node N1 remains the signal input in the phase t1, that is, the signal of the first output node N1 remains a low level. In this manner, the fifth control transistor M06 in the on state, and the high-level first clock signal XCK0 is transmitted to the second output node N2 through the fifth control transistor M06 so that the second output node N2 becomes a high level. The signal of the second output node N2 controls the second control transistor M07 to be turned off, and the second voltage signal VGH cannot be transmitted to the first output node N1 so that the signal of the first output node N1 is kept at a low level. At this time, the signal of the first output node N1 continues to control the first initial output transistor M01 and the first transistor M11 to be in the on state, while the second output node N2 controls both the second initial output transistor M02 and the second transistor M12 to be in the off state. In this way, the initial output signal Vnext is kept consistent with the low-level initial output control signal CK0, and the first output signal Gout1 is kept consistent with the low-level first output control signal CK1.

At phase t3, the input signal Vin is turned to the high level, the first clock signal XCK0 is turned to the low level, the initial output control signal CK0 and the first output control signal CK1 are both turned to the high level, thus, the first control transistor M04 and the fourth control transistor M05 are both turned on, the signal of the first output node N1 is consistent with the high-level input signal Vin, and signal of the second output node N2 is consistent with the low-level second voltage signal VGL, so that the signal of the first output node N1 controls the first initial output transistor M01 and the first transistor M11 to be both turned off, and the signal of the second output node N2 controls the second initial output transistor M02 and the second transistor M12 to be both turned on. At this time, the initial output signal Vnext and the first output signal Gout1 are both consistent with the high-level first voltage signal VGH.

After phase t3, the first output node N1 and the second output node N2 will continue to remain as the signals in phase t2 until the input signal Vin is turned to the low level again. Thus, when the initial output signal Vnext of an x^{th} stage shift register Gx serves as the input signal Vin of a y^{th} stage shift register Gy, the low-level signal of the initial output signal Vnext of the x^{th} stage shift register Gx and the low-level signal of the initial output signal Vnext of the y^{th} stage shift register Gy can sequentially shift, and meanwhile, the low-level signal of the first output signal Gout1 of the x^{th} stage shift register Gx of and the low-level signal of the first output signal Gout1 of the y^{th} stage shift register Gy can sequentially shift, so that the low-level signal of the initial output signals Vnext and the low-level signal of the first output signal Gout1 output by the shift register of each stage can shift sequentially. When the first output signals Gout1 output by the shift registers of all stages are used to control the signal refreshing time of the pixel circuits in each row, the pixel circuits in each row of the display panel can be scanned row by row.

It may be appreciated that when the low level of the initial output signal Vnext and the low level of the first output signal Gout1 output by the shift registers G of each stage shift sequentially, the low-level signal is just an active level capable of controlling the pixel circuits to perform signal refreshing. When the active level causing the pixel circuits to perform the signal refreshing is the high level, as shown in FIG. 18, it is possible to adaptively adjust the output time of the high level and low level of the initial output control signal CK0 and the output time of the high level and low level of the first output control signal CK1 as well as the type of each transistor in the shift registers, thus, the high level of the initial output signal Vnext and the high level of the first output signal Gout1 output by the shift registers G of each stage may just shift sequentially, so that the high-level signal can scan all pixel circuits row by row.

Alternatively, referring to FIG. 17 or FIG. 18, when the first output signal Gout1 output by the shift register can control a pixel circuit to perform signal refreshing, the pixel circuit may include a preset module, and in this case, the first output signal Gout1 of the shift register in the drive circuit is a control signal of the preset module in the pixel circuit, Moreover, when the first output signal Gout1 is an effective pulse, the preset module is turned on; and when the first output signal Gout1 is an ineffective pulse, the preset module is turned off. In this manner, the first output signal Gout1 can control the preset module in the pixel circuit to be turned on and off, thereby controlling the refreshing time of the signal at the node electrically connected to the preset module.

In one or more embodiments, as shown in FIG. 17, in a case where the preset module includes a PMOS type transistor and the first output signal is the control signal of the PMOS type transistor, when the first output signal Gout1 is a low-level signal, the first output signal Gout1 is an effective pulse, and controls the PMOS type transistor to be turned on; and when the first output signal Gout1 is a high-level signal, the first output signal Gout1 is an ineffective pulse, and controls the PMOS type transistor to be turned off.

In another embodiment, as shown in FIG. 18, in a case where the preset module includes an NMOS type transistor and the first output signal is the control signal of the NMOS type transistor, when the first output signal Gout1 is a high-level signal, the first output signal Gout1 is an effective pulse, and controls the NMOS type transistor to be turned on, and when the first output signal Gout1 is a low-level signal, the first output signal Gout1 is an ineffective pulse, and controls the NMOS type transistor to be turned off.

It may be appreciated that the preset module of the pixel circuit may be any one of the modules in the pixel circuit and may be selected on the basis of practical requirements. The pixel circuit and its preset module mentioned in the embodiments of the present disclosure are described below as a typical example.

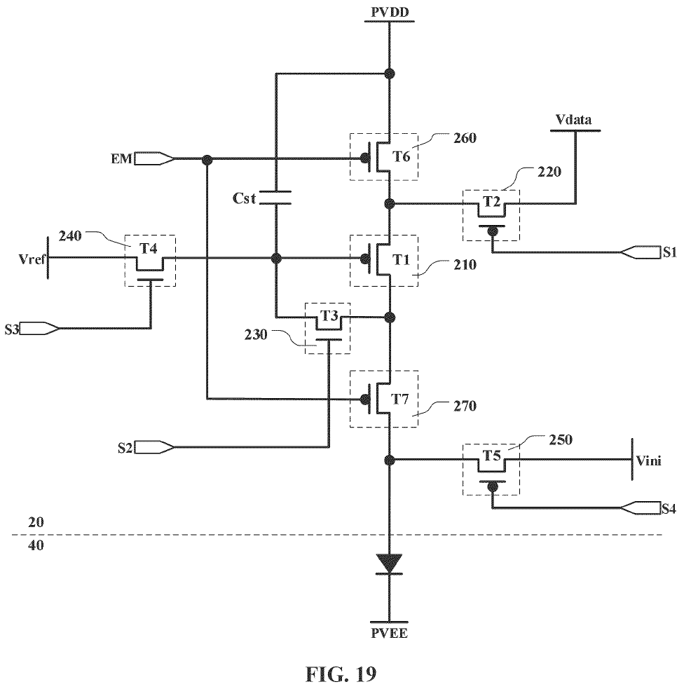

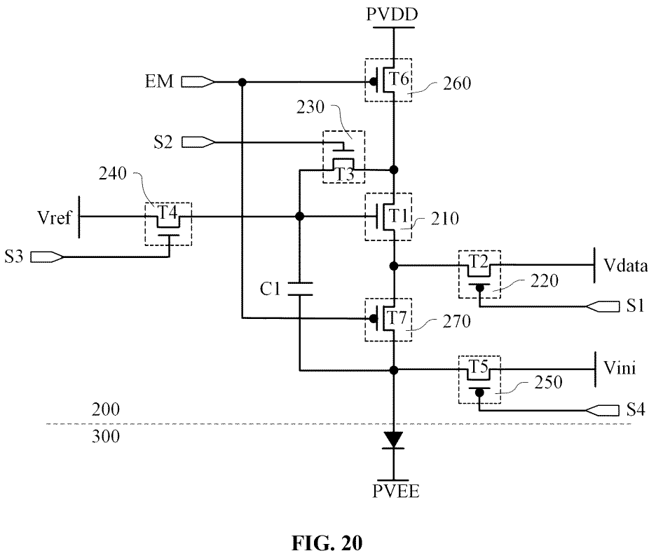

In one or more embodiments of the present disclosure, FIG. 19 is a schematic structural diagram of a pixel circuit according to an embodiment of the present disclosure. FIG. 20 is a schematic structural diagram of another pixel circuit according to an embodiment of the present disclosure. As shown in FIG. 19 or FIG. 20, the display panel includes a pixel circuit 20 and a light-emitting element 40. The pixel circuit 20 may include a drive module 210, a data writing module 220, a reset module 230 and a compensation module 230. The drive module 210 may selectively provide a drive current for the light-emitting element 40 to drive the light-emitting element 40 to emit light. The data writing module 220 is connected to a first terminal of the drive module 210 for providing a data signal Vdata to the drive module 210, so that the drive module 210 can generate the drive current for driving the light-emitting element 40 to emit light according to the data signal Vdata. The reset module 240 is connected to a control terminal of the drive module 210, for providing a reset signal to the drive module 210, to reset the drive module 210. The compensation module 230 is connected between the control terminal and a second terminal of the drive module 210, so that when the data writing module 220 provides the data signal Vdata for the drive module 210, the data signal Vdata is compensated, ensuring that the drive module 210 can provide an accurate drive current to the light-emitting element 40, to control accuracy of the light emission of the light-emitting element 40.

In one or more embodiments, the light-emitting element 40 is typically a current-type drive element, and the data signal Vdata provided by the data writing module 220 is typically a voltage signal, therefore, a drive transistor T1 is provided in the drive module 210, the data signal Vdata provided by the data writing module 220 can be written into a gate of the drive transistor T1, and the drive transistor T1 can generate a corresponding drive current according to the signal of the gate thereof, and provide the corresponding drive current to the light-emitting element 40 to drive the light-emitting element 40 to emit light of the corresponding brightness. In this case, one of a source and a drain of the drive transistor MI receives a positive power signal PVDD, and the other one is coupled to the anode of the light-emitting element 40, and the cathode of the light-emitting element 40 may receive a negative power signal PVEE. In this way, a voltage difference exists between the positive power signal PVDD and the negative power signal PVEE to form a current path, thereby the drive transistor T1 can generate a drive current and supply the drive current to the light-emitting element 40 to drive the light-emitting element 40 to emit light.

It may be appreciated that, as shown in FIG. 19, an active layer material of the drive transistor T1 in the drive module 210 may include a low-temperature polycrystalline silicon material such that the drive transistor T1 has a high carrier mobility, thereby meeting the requirements of high reaction speed and low power consumption, etc., and in this case, the drive transistor T1 may be a PMOS type transistor. In other embodiments, as shown in FIG. 20, the active layer material of the drive transistor T1 may also include an oxide semiconductor material, and in this case, the drive transistor T1 may be an NMOS type transistor. The material and the type of the drive transistor T1 are not limited in the embodiments of the present disclosure, on the premise that the core inventive point of the embodiments of the present disclosure can be realized.

Accordingly, the data writing module 220 may be connected to the first electrode of the drive transistor T1, for providing a data signal Vdata to the drive transistor T1. The compensation module 230 may be connected between the gate and the second electrode of the drive transistor T1, for compensating a threshold voltage of the drive transistor T1. The reset module 240 may be connected to the gate of the drive transistor T1, for providing a reset signal Vref to the gate of the drive transistor T1, to reset the gate of the drive transistor T.

The control terminal of the data writing module 220 may receive a first scan signal S1, and the first scan signal S1 controls the data writing module 220 to be turned on and off. The control terminal of the compensation module 230 may receive a second scan signal S2, and the second scan signal S2 controls the compensation module 230 to be turned on and off. The control terminal of the reset module 240 may receive a third scan signal S3, and the third scan signal S3 controls the reset module 240 to be turned on and off.

When the third scan signal S3 controls the reset module 240 to be turned on, the reset signal Vref may be transmitted to the gate of the drive transistor T1, to reset the gate of the drive transistor T1, so that the data signal Vdata provided to the gate of the drive transistor T1 in the previous drive cycle is cleared, and preparation for the writing of the subsequent data signal Vdata is made.

When the first scan signal S1 controls the data writing module 220 to be turned on, the data signal Vdata may be written into the first electrode of the drive transistor T1 through the data writing module 220 to refresh the signal of the first electrode of the drive transistor T1. At this time, if the drive transistor T1 is in the on state, and the second scan signal S2 controls the compensation module 230 to be turned on, the data signal Vdata may further be provided to the second electrode of the drive transistor T1 through the drive transistor T1, and provided to the gate of the drive transistor T1 through the compensation module 230, and the threshold voltage Vth of the drive transistor T1 is compensated to the gate of the drive transistor T1 so that the signals of the gate and the second electrode of the drive transistor T1 can be refreshed, to enable the drive current generated by the drive transistor T1 to be independent from the threshold voltage Vth of the drive transistor T1.

In an exemplary embodiment, the data writing module 220 may include a data writing transistor T2, a first electrode of the data writing transistor T2 receives the data signal Vdata, a second electrode of the data writing transistor T2 is electrically connected to the first electrode of the drive transistor T1, and a gate of the data writing transistor T2 receives the first scan signal S1 so that the first scan signal S1 controls the data writing transistor T2 to be turned on or off. The compensation module 230 includes a compensation transistor T3, a first electrode of the compensation transistor T3 is electrically connected to the second electrode of the drive transistor T1, a second electrode of the compensation transistor T3 is electrically connected to the gate of the drive transistor T1, and a gate of the compensation transistor T3 receives the second scan signal S2 so that the second scan signal S2 controls the compensation transistor T3 to be turned on or off. The reset module 240 may include a reset transistor T4, a first electrode of the reset transistor T4 receives a reset signal Vref, a second electrode of the reset transistor T4 is electrically connected to the gate of the drive transistor T1, and a gate of the reset transistor T4 receives the third scan signal S3 so that the third scan signal S3 to control the reset transistor T4 to be turned on or off.

On the basis of the above-described embodiments, the pixel circuit 20 may further include an initialization module 250, the initialization module 250 is connected to the anode of the light-emitting element 40, for providing an initialization signal Vini to the light-emitting element 40 to initialize the anode of the light-emitting element 40. The initialization module 250 may be turned on or off under the control of a fourth scan signal S4, when the fourth scan signal S4 controls the initialization module 250 to be turned on, the initialization signal Vini may be provided to the anode of the light-emitting element 40.

In an exemplary embodiment, the initialization module 250 may include an initialization transistor T5, a first electrode of the initialization transistor T5 receives the initialization signal Vini, a second electrode of the initialization transistor T5 is electrically connected to the anode of the light-emitting element 40, and a gate of the initialization transistor T5 receives the fourth scan signal S4 so that the fourth scan signal S4 controls the initialization transistor T5 to be turned on or off.

On the basis of the above-described embodiment, the pixel circuit 20 may further include a light emission control module. The light emission control module may include a first light emission control module 260 and a second light emission control module 270. The first light emission control module 260 and the second light emission control module 270 may control a current path between the positive power signal PVDD and the negative power signal PVEE, thereby controlling the time during which the drive transistor T1 provides the drive current for the light-emitting element 40. The first light emission control module 260 and the second light emission control module 270 may be turned on or off under the control of a light emission control signal EM, when the light emission control signal EM controls the first light emission control module 260 and the second light emission control module 270 to be turned on, the drive transistor T1 can generate the drive current and provide the drive current to the light-emitting element 40 to drive the light-emitting element 40 to emit light.

In an exemplary embodiment, the first light emission control module 260 may include a first light emission control transistor T6, and the second light emission control module 270 may include a second light emission control transistor T7. A first electrode of the first light emission control transistor T6 receives the positive power signal PVDD, a second electrode of the first light emission control transistor T6 is electrically connected to the first electrode of the drive transistor T1, a first electrode of the second light emission control transistor T7 is electrically connected to the second electrode of the drive transistor T1, a second electrode of the second light emission control transistor T7 is electrically connected to the anode of the light-emitting element 40, and both a gate of the first light emission control transistor T6 and a gate of the second light emission control transistor T7 receive the light emission control signal EM so that the light emission control signal EM can control both the first light emission control transistor T6 and the second light emission control transistor T7 to be turned on or off at the same time.

On the basis of the above-described embodiment, the pixel circuit 20 may further include a storage capacitor Cst, a first plate of the storage capacitor Cst receives a fixed signal (e.g., the positive power signal PVDD) and a second plate of the storage capacitor Cst is electrically connected to the gate of the drive transistor T1 to store the signal at the gate of the drive transistor T1.

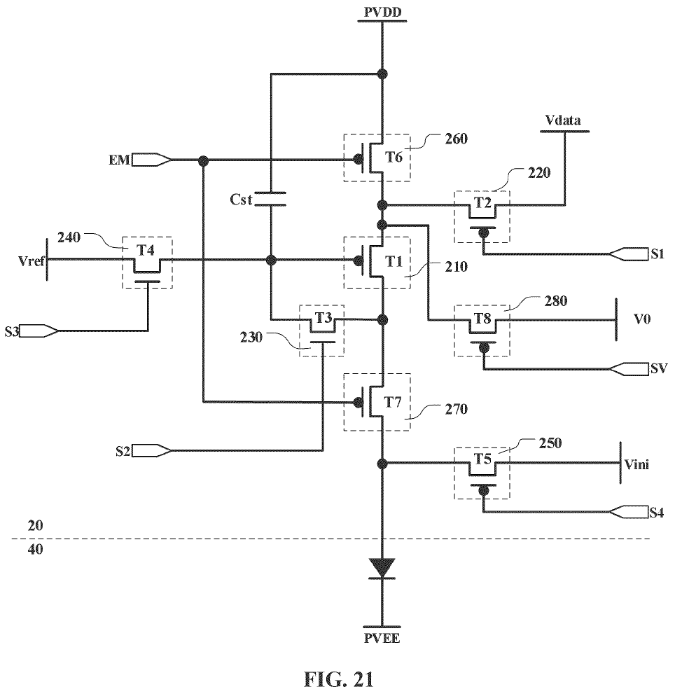

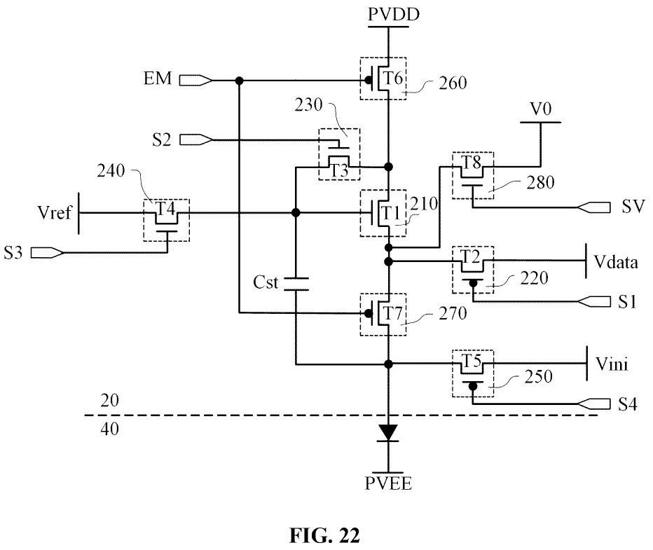

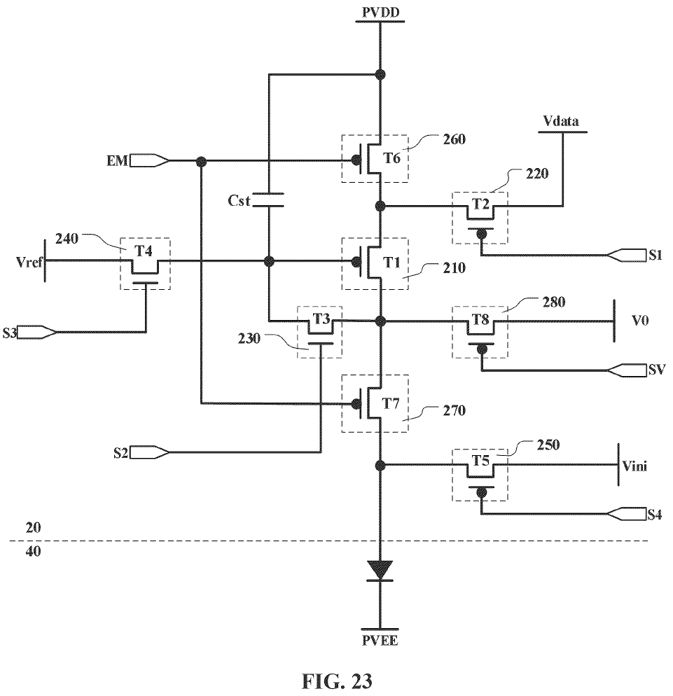

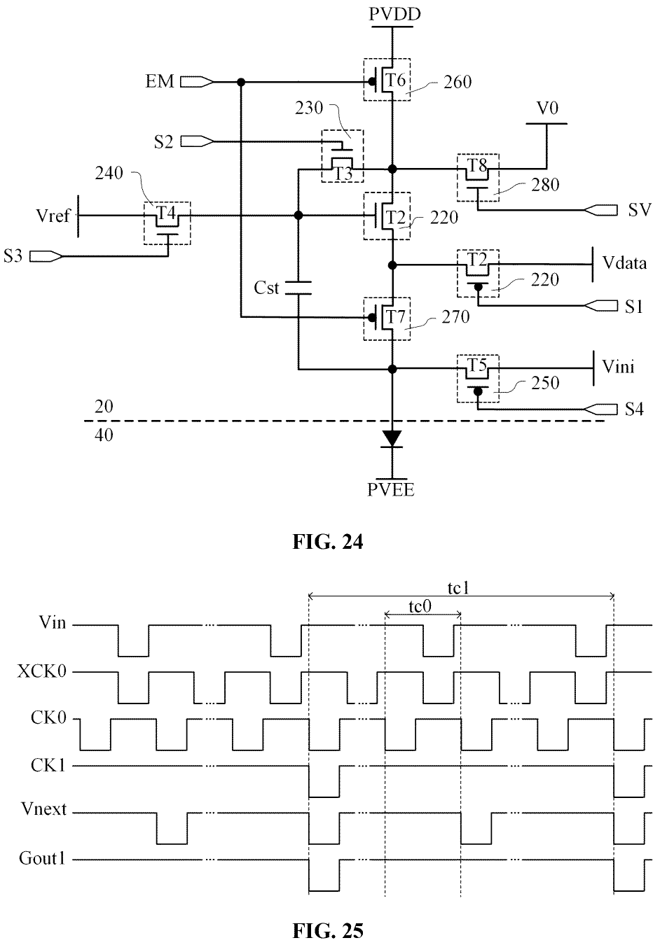

In another embodiment of the present disclosure, FIG. 21 to FIG. 24 are schematic structural diagrams of another pixel circuit according to an embodiment of the present disclosure, with reference to any one of FIG. 21 to FIG. 24, on the basis of the above-described embodiments, the pixel circuit 20 may further include a bias adjustment module 280. The bias adjustment module 280 is connected to the first terminal or the second terminal of the drive module 210, for providing a bias adjustment signal V0 to the drive module 210, for performing bias adjustment on the drive transistor T1 in the drive module 210.

When the drive module 210 includes the drive transistor T1, the first electrode of the drive transistor T1 may be the first terminal of the drive module 210, and the second electrode of the drive transistor T1 may be the second terminal of the drive module 210, in this case, the bias adjustment module 280 may be electrically connected to the first electrode or the second electrode of the drive transistor T1, which is not limited in the embodiments of the present disclosure on the premise that the bias adjustment on the drive transistor T1 can be implemented.

In one or more embodiments, the bias adjustment module 280 may be turned on or off under the control of a bias adjustment control signal SV, when the bias adjustment control signal SV controls the bias adjustment module 280 to be turned on, the bias adjustment signal V0 may be provided to the first electrode and/or second electrode of the drive transistor T1 to perform the bias adjustment on the drive transistor T1.

In an exemplary embodiment, the bias adjustment module 280 may include a bias adjustment transistor T8, a first electrode of the bias adjustment transistor T8 receives the bias adjustment signal V0, a second electrode of the bias adjustment transistor T8 is electrically connected to the first electrode or the second electrode of the drive transistor T1, and a gate of the bias adjustment transistor T8 receives the bias adjustment control signal SV so that the bias adjustment control signal SV controls the bias adjustment transistor T8 to be turned on or off.

It is to be noted that FIG. 19 to FIG. 24 show, by way of example only, configurations of several pixel circuits rather than including all, and the structure of the pixel circuit is not limited in the embodiments of the present disclosure, on the premise that the core inventive point of the embodiments of the present disclosure can be realized.

Based on the above-described pixel circuits, the drive circuit in the embodiments of the present disclosure may correspondingly provide the control signal to any one of the data writing module 220, the compensation module 230, the reset module 240, the initialization module 250, the light emission control module (the first light emission control module 260 and the second light emission control module 270), and the bias adjustment module 280, so that the preset module of the pixel circuit 200 may be any one of the data writing module 220, the compensation module 230, the reset module 240, the initialization module 250, the light emission control module (the first light emission control module 260 and the second light emission control module 270), and the bias adjustment module 280, that is, the first output signal of the drive circuit may be any one of the first scan signal S1, the second scan signal S2, the third scan signal S3, the fourth scan signal S4, the light emission control signal EM, and the bias adjustment control signal SV. The driving principle of the pixel circuit 20 is described hereinafter by taking it as an example that the first output signal of the drive circuit is the first scan signal S1 for controlling the data writing module 220 to be turned on or off.

With reference to FIG. 2 and FIG. 19 (or any one of FIG. 20 to FIG. 24), different stages of shift registers G may provide the first output signals Gout1 to the pixel circuits 20 in different rows to control the data writing models 220 in the pixel circuits 20 of each row to be turned on or off. An x^{th} stage shift register and a y^{th} stage shift register are taken as an example. When it is required to control the data writing module 220 to provide the data signal Vdata for the drive module 210, after the x^{th} stage shift register receives an effective pulse of the input signal Vin, the x^{th} stage shift register may be controlled to output an effective pulse of the first output signal Gout1 to the pixel circuits 20 in an x^{th} row to turn on the data writing modules 220 of the pixel circuits 20 in the x^{th} row, and the data signal Vdata is written into the drive modules 210 of the pixel circuits 20 in the x^{th} row. Meanwhile, the x^{th} stage shift register may further output an effective pulse of the initial output signal Vnext to the y^{th} stage shift register, such that after the x^{th} stage shift register outputs the effective pulse of the initial output signal Vnext, the drive modules 210 of the pixel circuits 20 in the x^{th} row are turned off, and the y^{th} stage shift register outputs an effective pulse of the first output signal Gout1 to the pixel circuits 20 in a y^{th} row, thus, the data writing modules 220 of the pixel circuits 20 in the y^{th} row are turned on, and the data signal Vdata is written into the drive modules 210 of the pixel circuits 20 in the y^{th} row. Meanwhile, the y^{th} stage shift register may further output an effective pulse of the initial output signal Vnext. In this way, the shift register G of each stage provides an active-level initial output signal Vnext to the next stage shift register, meanwhile, the shift register G of each stage can further provide the first output signal Gout1 to the data writing modules 220 of the pixel circuits 20 so that the first output signal Gout1 for controlling the data writing modules 220 and the initial output signal Vnext provided to the next stage shift register are signals having different polarities and/or amplitudes, to ensure that the next stage shift register can operate normally, and also that the data signal Vdata of the drive modules 210 in the pixel circuits 20 can be refreshed normally, preventing the normal display and light emission of the display panel 100 from being adversely affected when the input signal Vin required by the shift register and the control signal required by the pixel circuit 20 are different, thereby meeting the diversified functional requirements.

For the cases where the first output signal Gout1 output by the drive circuit 10 is the control signal of other modules in the pixel circuit 20, they are similar to the case described above, and the embodiments of the present disclosure will not repeat here.

It may be appreciated that the above description illustrates the working process of the shift register G and the driving process of the preset module in the pixel circuit 20 by the first output signal Gout1 output by the shift register by taking an example that the pulse change frequency Fc0 of the initial output control signal CK0 is the same as the pulse change frequency Fc1 of the first output control signal CK1. However, in other embodiments of the present disclosure, within at least a part of the time period of the working process of the display panel, the pulse change frequency Fc0 of the initial output control signal CK0 may be different from the pulse change frequency Fc1 of the first output control signal CK1, that is, Fc0 #Fc1.

In one or more embodiments, FIG. 25 is a drive timing diagram of another shift register according to an embodiment of the present disclosure. As shown in FIG. 25, when the pulse change frequency of the initial output control signal CK0 is Fc0 and the pulse change frequency of the first output control signal CK1 is Fc1, it may be Fc0>Fc1.

The shift register shown in FIG. 16 is taken as an example, with reference to FIG. 16 and FIG. 25, the signal of the first output node N1 can simultaneously control the initial output signal Vnext output by the first initial output module 121 and the first output signal Gout1 output by the first output module 1311, so that when the signal of the first output node N1 is an active level, the first initial output module 121 can keep the initial output signal Vnext consistent with the initial output control signal CK0, and the first output module 1311 can enable the first output signal Gout1 consistent with the first output control signal CK1. Therefore, when the pulse change frequency Fc0 of the initial output control signal CK0 is greater than the pulse change frequency Fc1 of the first output control signal CK1, that is, when the pulse period of the initial output control signal CK0 is smaller than the pulse period of the first output control signal CK1, the pulse change frequency of the initial output signal Vnext may be greater than the pulse change frequency of the first output signal Gout1, in other words, the pulse period of the initial output signal Vnext may be smaller than the pulse period of the first output signal Gout1. In this manner, for a period of time, the number of effective pulses of the initial output signal Vnext will be larger than the number of effective pulses of the first output signal Gout1, so that in this period of time, even if signal refreshing is not required to be performed on the pixel circuits 20 electrically connected to the shift register G, the initial output signal Vnext output by the shift register G can control another shift register electrically connected to the initial output unit 120 to work normally, ensuring that the display panel can display an image normally.

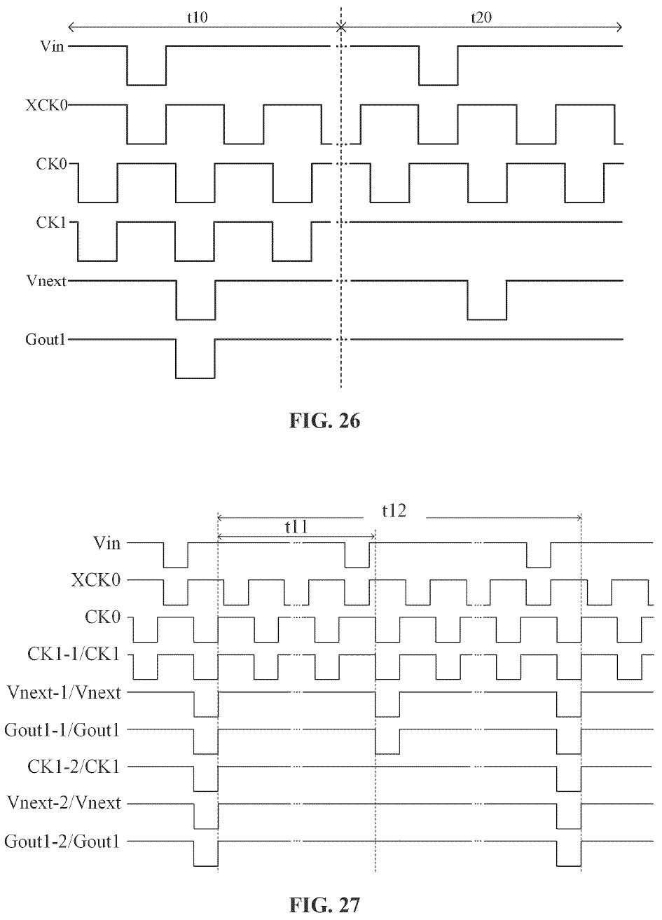

In another embodiment, FIG. 26 is a drive timing diagram of another shift register according to an embodiment of the present disclosure. As shown in FIG. 26, in a case where the working process of the display panel includes a first time period t10 and a second time period t20, in the first time period t10, when the initial output control signal CK0 is an effective pulse, the first output control signal CK1 is an effective pulse; and in the second time period t20, when the initial output control signal CK0 is an effective pulse, the first output control signal CK1 is an ineffective pulse.

As such, the pulse change frequency of the initial output control signal CK0 in the first time period t10 may be the same as the pulse change frequency of the first output control signal CK1, while in the second time period t20, the pulse change frequency of the initial output control signal CK0 may be greater than the pulse change frequency of the first output control signal CK1, such that in the first time period t10, the effective pulse time of the initial output signal Vnext is kept consistent with the effective pulse time of the first output signal Gout1, while in the second time period t20, the initial output signal Vnext may include an active level and the first output signal Gout1 may remain an inactive level. In this manner, the first output signal Gout1 and the initial output signal Vnext may be adjusted adaptively in different time periods, such that the display panel meets the diversified functional requirements.

In another embodiment, FIG. 27 is a drive timing diagram of another shift register according to an embodiment of the present disclosure. As shown in FIG. 27, the working process of the display panel may further include a first mode and a second mode. In the first mode, the pulse change frequency of the first output control signal CK1-1 is Fc11, and in the second mode, the pulse change frequency of the first output control signal CK1-2 is Fc12; and Fc11≠Fc12.

It may be appreciated that in the working process of the display panel, the display panel may have different working modes, e.g., the display panel may include a first mode and a second mode, and the refresh rate and/or display brightness of the display panel in the first mode may be different from the refresh rate and/or display brightness of the display panel in the second mode, thereby enabling the display panel to meet different display requirements.

The refresh rate of the display panel is just the writing frequency for writing the data signal to the gate of the drive transistor of the pixel circuit in the display panel, and typically, the time of one frame image may include a data writing frame and a retention frame, that is, the working process of the pixel circuit may include a data writing frame and a retention frame. In the data writing frame, the signal of the gate of the drive transistor in the pixel circuit may be refreshed to clear the data signal written into the gate of the drive transistor in the pixel circuit in the time of the previous frame, and write a data signal corresponding to the current frame to the gate of the drive transistor in the pixel circuit. While in the retention frame, the signal at the gate of the drive transistor in the pixel circuit remains unchanged until entering the data writing frame of the next frame.

Illustratively, when the display panel maintains the same display content within a relatively long time period, for example, when the display panel is in standby mode, it is possible to make the display panel have a relatively low refresh rate, that is, the duration of the retention frame in the working process of the pixel circuit is relatively long, so that in a relatively long time, it is not necessary to refresh the signal at the gate of the drive transistor in the pixel circuit to reduce the power consumption caused by the data refresh, thereby facilitating the low power consumption of the display panel. When the image displayed by the display panel is switched in real time, for example, the display panel may be configured to have a relatively high refresh rate when the display panel is in a video display mode, that is, the duration of the retention frame in the working process of the pixel circuit is relatively short. Therefore, it is necessary to refresh the signal at the gate of the drive transistor in real time so that when the drive transistor generates the drive current according to the signal at the gate of the drive current to drive the light-emitting element to emit light, the accurate light emission of the light-emitting element can be ensured, thereby facilitating the improvement of the image flicker generated when the display panel performs image display, and improving the smoothness of the displayed image.

Since the pulse change frequency of the first output control signal CK1 can control the pulse change frequency of the effective pulse of the first output signal Gout1 output by the shift register, and the first output signal Gout1 can control the signal refresh rate at the corresponding node in the pixel circuit, when the first output control signal CK1 has different pulse change frequencies in different modes, the first output signal Gout1 may also have different pulse change frequencies in different modes so that the signal refresh rates at the corresponding node in the pixel circuit are different in different modes to meet different display requirements of the display panel.

In one or more embodiments, when in the first mode, the pulse change frequency of the first output control signal CK1-1 is Fc1l and the pulse change frequency of the first output signal Gout1-1 is Fs1; in the second mode, the pulse change frequency of the first output control signal CK1-2 is Fc12 and the pulse change frequency of the first output signal Gout1-2 is Fs12, and Fc11≠Fc12 and Fs11≠Fs12, there may be (Fc11−Fc12)×(Fs11−Fs12)>0, so that the pulse change frequency of the first output signal Gout1 increases as the pulse change frequency of the first output control signal CK1 increases, and conversely, the pulse change frequency of the first output signal Gout1 may also decrease as the pulse change frequency of the first output control signal CK1 decreases, thus, the pulse change frequency of the first output signal Gout1 can be kept consistent with the pulse change frequency of the first output control signal CK1.

In one or more embodiments, in a case where the first output signal Gout1 is the signal that controls the preset module in the pixel circuit to be turned on or turned off, and the working process of the pixel circuit includes a data writing frame and a retention frame, the preset module may be turned on in the data writing frame and turned off in the retention frame.

Illustratively, the pixel circuit 20 shown in FIG. 21 is taken as an example, with reference to FIG. 21 and FIG. 27, in a non-light emission stage of the data writing frame, the reset module 240 may be controlled to be turned on so that the reset signal is provided to the gate of the drive transistor T1, thereby resetting the gate of the drive transistor T1, and after the gate of the drive transistor T1 is reset, the data writing module 220 and the compensation module 230 may be controlled to be turned on so that the data signal is written into the gate of the drive transistor T1 through the data writing module 220, the drive transistor T1 and the compensation module 230, and the threshold voltage Vth of the drive transistor T1 is compensated to the gate of the drive transistor T1. In a light emission stage of the data writing frame, the first light emission control module 260 and the second light emission control module 270 may be controlled to be turned on so that the drive transistor T1 generates the drive current to provide the drive current to the light-emitting element 40 to drive the light-emitting element 40 to emit light. In a non-light emission stage of the retention frame, the bias adjustment module 280 may be controlled to be turned on, while the other modules may be all in the off state, so that bias adjustment can be performed on the drive transistor T1 by using a bias adjustment signal. In a light emission stage of the retention frame, only the first light emission control module 260 and the second light emission control module 270 are turned on and the other modules are all in the off state, such that the drive transistor T1 generates the drive current and provides to the light-emitting element 40 to drive the light-emitting element 40 to emit light. In this way, the modules that are in the on state in the data writing frame and in the off state in the retention frame may include any one of the reset module 240, the compensation module 230 and the data writing module 220.

In one or more embodiments, the data refresh rate of the pixel circuit in the first mode is Fp1, the data refresh rate of the pixel circuit in the second mode is Fp2, and Fp1≠Fp2.

Illustratively, the pixel circuit 20 shown in FIG. 21 and the shift register shown in FIG. 16 are taken as an example, with reference to FIG. 16, FIG. 21 and FIG. 27, the data refresh rates of the pixel circuit 20 in the first mode and second mode are different, so the data refresh interval time of the pixel circuit 20 is different in the first mode and the second mode, that is, the duration of the retention frame of the pixel circuit 20 is different in the first mode and the second mode. When the first output signal Gout1 is the signal that controls the data writing module 220 in the pixel circuit 20 to be turned on or off, the first output control signal CK1 is controlled to have different pulse change frequencies when the display panel is in different modes, so that the first output signal Gout1 output by the first output module 1311 receiving the first output control signal CK1 has different pulse change frequencies. For example, in the first mode, the first output control signal CK1 has a high pulse change frequency Fc11 so that the interval time between the effective pulses of the first output signal Gout1-1 is short, and the turning-on interval time of the data writing module 220 is short. After the data writing module 220 is turned on and the data signal Vdata of the previous frame is provided to the drive module 210, the data writing module 220 may be turned on again after interval t11, such that the data signal Vdata of the current frame is provided to the drive module 210, the data signal Vdata provided to the drive module 210 can be refreshed at a short interval, and the pixel circuit 20 can have a high data refresh rate Fp1. However, in the second module, the first output control signal CK1 has a low pulse change frequency Fc12 so that the interval time between the effective pulses of the first output signal Gout1-2 is long, and the turning-on interval time of the data writing module 220 is long. After the data writing module 220 is turned on and the data signal Vdata of the previous frame is provided to the drive module 210, the data writing module 220 may be turned on again after interval t12, such that the data signal Vdata of the current frame can be provided to the drive module 210, the data signal Vdata provided to the drive module 210 can be refreshed at a long interval, and the pixel circuit 20 to have a low data refresh rate Fp2. In this way, the first output control signal CK1 has different pulse change frequencies in different modes so that the pixel circuit 20 can have different data refresh rates in different modes, thereby facilitating the low power consumption and high display quality of the display panel, and enabling the display panel to meet diversified display requirements.

It may be appreciated that the data refresh rate of the pixel circuit 20 is positively correlated with the pulse change frequency of the first output control signal. In one or more embodiments, in a case where the display panel includes the first mode and the second mode, in the first mode, the data refresh rate of the pixel circuit is Fp1 and the pulse change frequency of the first output control signal CK1 is Fc11, and in the second mode, the data refresh rate of the pixel circuit is Fp2 and the pulse change frequency of the first output control signal CK1 is Fc12. If Fc11 is greater than Fc12, Fp1 is greater than Fp2, or if Fc1l is less than Fc12, Fp1 is less than Fp2, namely, (Fp1−Fp2) is positively correlated with (Fc11−Fc12), resulting in (Fp1−Fp2)×(Fc11−Fc12)>0.

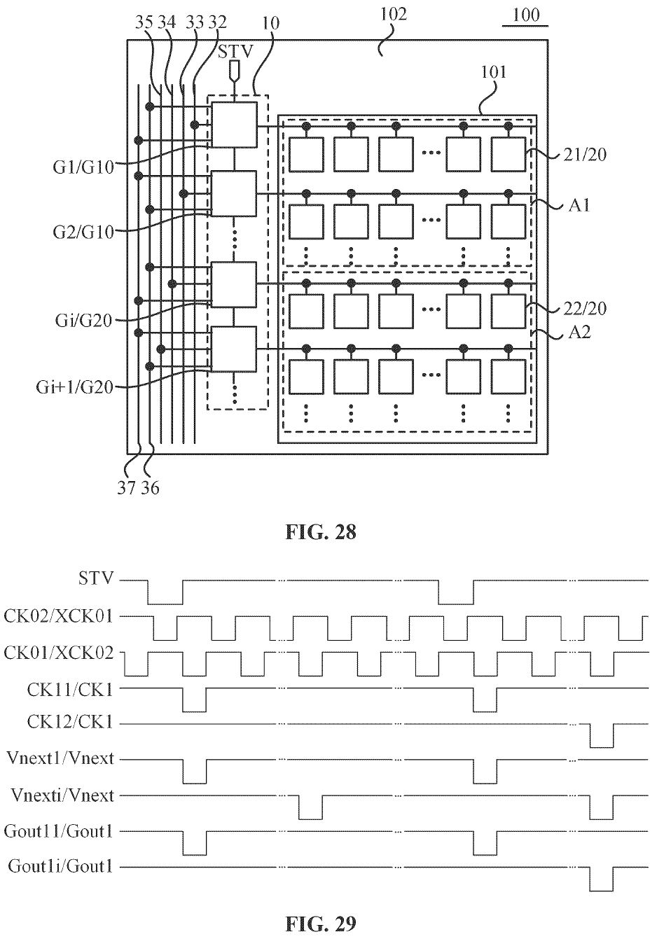

FIG. 28 is a schematic structural diagram of another display panel according to an embodiment of the present disclosure. FIG. 29 is the drive timing diagram of another drive circuit according to an embodiment of the present disclosure. With reference to FIG. 28 and FIG. 29, in a case where the display panel 100 includes a first pixel circuit 21 and a second pixel circuit 22, the drive circuit 10 may include a first shift register G10 and a second shift register G20. A first output signal Gout1 of the first shift register G10 is a control signal of the preset module in the first pixel circuit 21, and a first output signal Gout2 of the second shift register G20 is a control signal of the preset module in the second pixel circuit 22. The pulse change frequency of the first output control signal CK11 received by the first shift register G10 is Fct1, the pulse change frequency of the first output control signal CK12 received by the second shift register G20 is Fct2, and Fct1≠Fct2.

It may be appreciated that the pulse change frequency of the first output signal Gout1 output by the shift register is correlated with the pulse change frequency of the first output control signal CK1 received by the shift register, and generally, the pulse change frequency of the first output signal Gout1 may be the same as the pulse change frequency of the first output control signal CK1, so that when the pulse change frequency Fct1 of the first output control signal CK11 received by the first shift register G10 is different from the pulse change frequency Fct2 of the first output control signal CK12 received by the second shift register G20, the pulse change frequency of the first output signal Gout1 output by the first shift register G10 is different from the pulse change frequency of the first output signal Gout1 output by the second shift register G20, that is, when the pulse change frequency of the first output signal Gout1 received by the preset module of the first pixel circuit 21 is Fs11, and the pulse change frequency of the first output signal Gout1 received by the preset module of the second pixel circuit 22 is Fs22, Fs11≠Fs22.

In one or more embodiments, when the preset module of the pixel circuit 20 is turned on to enable the pixel circuit 20 to perform data refresh, the first output control signal CK11 received by the first shift register G10 and the first output control signal CK12 received by the second shift register G20 are configured to have different pulse change frequencies, so that the preset module in the first pixel circuit 21 and the preset module in the second pixel circuit 22 can have different turning on cycles, and further the first pixel circuit 21 and the second pixel circuit 22 can have different data refresh rates, that is, when the data refresh rate of the first pixel circuit 21 is Fp11, and the data refresh rate of the second pixel circuit 22 is Fp22, Fp11≠Fp22.

Correspondingly, since the pulse change frequency of the first output signal Gout1 of the shift register is consistent with the pulse change frequency of the first output control signal CK1 received by the shift register, and the first output signal Gout1 is used to control the turning on and off of the preset module in the pixel circuit 20, so that the turning-on frequency of the preset module in the pixel circuit 20 keeps consistent with the pulse change frequency of the first output signal Gout1. Therefore, the turning-on frequency of the preset module in the pixel circuit 20 is consistent with the pulse change frequency of the first output control signal CK1 so that the refresh rate of the pixel circuit 20 is consistent with the pulse change frequency of the first output control signal CK1, that is, the refresh rate of the pixel circuit 20 increases as the pulse change frequency of the first output control signal CK1 increases. In this way, when (Fct1−Fct2) is a positive value, (Fp11−Fp22) is also a positive value, or when (Fct1−Fct2) is a negative value, (Fp11−Fp22) is also a negative value, that is, (Fp11−Fp22)×(Fct1−Fct2)>0.

In an exemplary embodiment, with reference to FIG. 28 and FIG. 29, the case that the first stage shift register G1 is the first shift register G10 and an i^{th} stage shift register Gi is the second shift register G20 is taken as an example. When the pulse change frequency of the first output control signal CK11 received by the first stage shift register G1 is greater than the pulse change frequency of the first output control signal CK12 received by the i^{th} stage shift register, the pulse change frequency of the first output signal Gout11 output by the first stage shift register G1 will be greater than the pulse change frequency of the first output signal Gout1i output by the i^{th} stage shift register Gi. In this case, the data refresh rate of the first pixel circuit 21 receiving the first output signal Gout11 output by the first stage shift register G1 is greater than the data refresh rate of the second pixel circuit 22 receiving the first output signal Gout1i output by the i^{th} stage shift register Gi. Meanwhile, since the initial output control signal (CK01) received by the first stage shift register G1 and the initial output control signal (CK01) received by the i^{th} stage shift register Gi are the same initial output control signal, the initial output signal Vnext1 of the first stage shift register G1 can have the same pulse output frequency as the initial output signal Vnexti of the i^{th} stage shift register Gi, thereby ensuring that the first shift register G10 and the second shift register G20 in the drive circuit can both work normally.

In one or more embodiments, in a case where the display panel 100 includes the first display region A1 and the second display region A2, the first pixel circuit 21 may be located in the first display region A1, and the second pixel circuit 22 may be located in the second display region A2. In this case, the pulse change frequency of the first output control signal CK11 received by the first shift register G10 for controlling the preset module in the first pixel circuit 21 to be turned on or off is Fct1, and the pulse change frequency of the first output control signal CK12 received by the second shift register G20 for controlling the preset module in the second pixel circuit 22 to be turned on or off is Fct2, so that the first pixel circuit 21 and the second pixel circuit 22 have different data refresh rates, that is, the data refresh rate of the first pixel circuit 21 in the first display region A1 is different from the data refresh rate of the second pixel circuit 22 in the second display region A2, thereby meeting the normal display requirements of the display panel 100, and also enabling the display panel 100 to have lower power consumption, so that the display panel 100 can meet diversified display requirements.

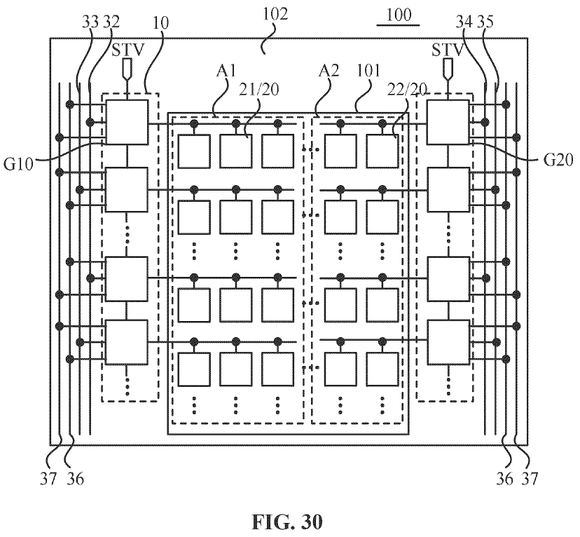

It is to be noted that in FIG. 28, an illustrative description is made simply by taking an example in which the first pixel circuit 21 and the second pixel circuit 22 are located in different rows, the first shift register G10 and the second shift register G20 are located at the same side of the display region 101, and the first shift register G10 and the second shift register G20 are cascaded. In this case, the first display region A1 and the second display region A2 are arranged in the column direction of the pixel circuits 20. In other embodiments of the present disclosure, as shown in FIG. 30, at least part of the first pixel circuit 21 may be located in the same row as at least part of the second pixel circuit 22, and the first display region A1 and the second display region A2 can be arranged in the row direction of the pixel circuits 20. The first shift register G10 and the second shift register G20 can be located on different sides of the display region 101, respectively, so that the initial output signal Vnext output by the first shift register G10 and the initial output signal Vnext output by the second shift register G20 are independent of each other. Through controlling the first output control signal CK11 received by the first shift register G10 and the second output control signal CK12 received by the second shift register G20 to be different from each other, the first pixel circuit 21 and the second pixel circuit 22 can have different data refresh rates as well. Therefore, the setting method of the first shift register G10 and the second shift register G20 is not limited in the embodiments of the present disclosure on the premise that the core inventive point of the embodiments of the present disclosure can be realized. To facilitate the description, the embodiments of the present disclosure are illustrated by taking the setting method of the shift registers shown in FIG. 28 as an example.

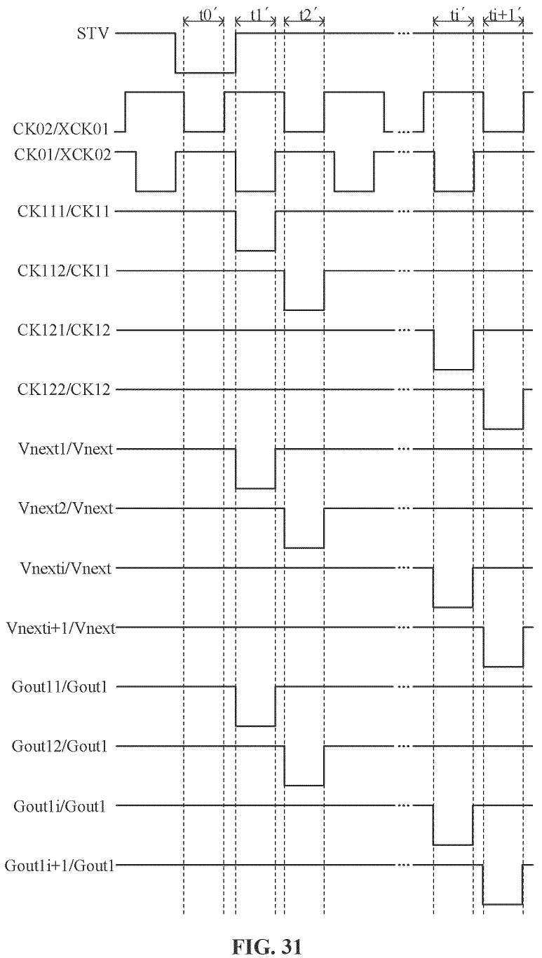

In one or more embodiments, FIG. 31 is a drive timing diagram of another drive circuit according to an embodiment of the present disclosure. The shift register shown in FIG. 16 is taken as an example, and reference is made to FIG. 16, FIG. 28 and FIG. 31, if the initial output signal Vnext output by the shift register G of each stage in the drive circuit 10 is required to shift sequentially, and the first output signal Gout1 output by the shift register G of each stage is also required to shift sequentially, in time period t0′, the first clock signal XCK01 received by the first stage shift register G1 is an active level so that an active level of a start signal STV is transmitted to the first output node N1, the signal of the first output node N1 can control the first initial output module 121 of the first stage shift register G1 to output the initial output control signal CK01 received by the first initial output module 121 as the initial output signal Vnext1, and the signal of the first output node N1 can also control the first output unit 1311 of the first stage shift register G1 to output the first output control signal CK111 received by the first output unit 1311 as the first output signal Gout11. Since both the initial output control signal CK01 and the first output control signal CK111 received by the first stage shift register G1 at this time are the inactive level, the initial output signal Vnext1 and the first output signal Gout11 output by the first stage shift register G1 are both the inactive level. Meanwhile, the initial output signal Vnext1 of the first stage shift register G1 is the input signal Vin of the second stage shift register G2, so that the signal of the first output node N1 in the second stage shift register G2 in this time period cannot control the first initial output module 121 and the first output unit 1311 of the second stage shift register G2 to be turned on, thus the initial output signal Vnext2 and the first output signal Gout12 output by the second stage shift register G2 are both the inactive level. For shift registers of other stages (an i^{th} stage shift register Gi, an (i+1)^{th} stage shift register Gi+1), all have a similar case as the second stage shift register G2, and all the initial output signal Vnext (Vnexti, Vnexti+1) and the first output signal Gout1 (Gout1i, Gout1i+1) output by the shift registers of other stages (the i^{th} stage shift register Gi, the (i+1)^{th} stage shift register Gi+1) are the inactive level.

In time period t1′, the first clock signal XCK01 received by the first stage shift register G1 is turned to the inactive level, the start signal STV is also turned to the inactive level, and the signal of the first output node N1 maintains the signal in time period t0′, so that the first initial output module 121 of the first stage shift register G1 continues to output the initial output control signal CK01 received by the first initial output module 121 as the initial output signal Vnext1, and the first output unit 1311 of the first stage shift register G1 continues to output the first output control signal CK111 received by the first output unit 1311 as the first output signal Gout11. At this time, since the initial output control signal CK01 and the first output control signal CK111 received by the first stage shift register G1 are both turned to the active level, the initial output signal Vnext1 and the first output signal Gout11 output by the first stage shift register G1 are both turned to the active level. Furthermore, since the initial output signal Vnext1 of the first stage shift register G1 is the input signal Vin of the second stage shift register G2, the first clock signal XCK02 received by the second stage shift register G2 should be the active level, so that the signal of the first output node N1 in the second stage shift register G2 in this time period is kept consistent with the initial output signal Vnext1 of the first stage shift register G1, the initial output signal Vnext2 output by the second stage shift register G2 is kept consistent with the initial output control signal CK02 received by the second stage shift register G2, and the first output signal Gout12 output by the second stage shift register G2 is kept consistent with the first output control signal CK112 received by the second stage shift register G2. In addition, to ensure that the initial output signals Vnext and the first output signals Gout1 output by the first shift register G1 and the second shift register G2 can shift sequentially, in this time period, the initial output control signal CK02 and the first output control signal CK112 may be the inactive level. In this way, during this time period, the initial output control signal CK01 received by the first stage shift register G1 is different from the initial output control signal CK02 received by the second stage shift register G2, and the first output control signal CK111 received by the first stage shift register G1 is different from the first output control signal CK112 received by the second stage shift register G2, while the initial output control signal CK01 received by the first stage shift register G1 is the same as the first clock signal XCK02 received by the second stage shift register G2, and the first clock signal XCK01 received by the first stage shift register G1 is the same as the initial output control signal CK02 received by the second stage shift register G2.

In time period t2′, the initial output control signal CK01 and the first output control signal CK111 received by the first stage shift register G1 are each the inactive level, while the first clock signal XCK01 received by the first stage shift register G1 is turned to the active level, so that the initial output control signal CK02 and the first output control signal CK112 received by the second stage shift register G2 are all turned to the active level, and the initial output signal Vnext2 and the first output signal Gout12 of the second stage shift register G2 are each the active level. During this time period, the initial output control signal CK01 received by the first stage shift register G1 is different from the initial output control signal CK02 received by the second stage shift register G2, and the first output control signal CK111 received by the first stage shift register G1 is different from the first output control signal CK112 received by the second stage shift register G2, while the initial output control signal CK01 received by the first stage shift register G1 is the same as the first clock signal XCK02 received by the second stage shift register G2, and the first clock signal XCK01 received by the first stage shift register G1 is the same as the initial output control signal CK02 received by the second stage shift register G2. In this manner, the initial output control signal CK01 of the first stage shift register G1 can be used as the first clock signal XCK02 of the second stage shift register G2, and the initial output control signal CK02 of the second stage shift register G2 can be used as the first clock signal XCK01 of the first stage shift register G1, thereby reducing the number of signals provided to the shift registers of all stages, and reducing pins of a driving chip for providing signals to the shift registers of all stages, and further facilitating the simplification of the structure of the driving chip and facilitating the low cost of the driving chip. Moreover, the non-display region 102 of the display panel 100 may further be provided with signal lines (37, 36, 32, 33, 34 and 35) for transmitting the first clock signal XCK0, the initial output control signal CK0 and the first output control signals CK111, CK112, CK121 and CK122. When the first clock signals XCK0 are used as the initial output control signals CK0 of different stages, the number of signal lines set in the non-display region 102 can be reduced, thereby facilitating the realization of the narrow bezel of the display panel 100.

Correspondingly, in time period ti′, the state of an i^{th} stage shift register Gi is similar to the state of the first stage shift register G1 in time period t1′, and the state of an (i+1)^{th} stage shift register Gi+1 is similar to the state of the second stage shift register G2 in time period t1′. In time period ti+1′, the state of the i^{th} stage shift register Gi is similar to the state of the first stage shift register G1 in time period t2′, and the state of the (i+1)^{th} stage shift register Gi+1 is similar to the state of the second stage shift register G2 in time period t2′. Therefore, the initial output control signal CK01 of the i^{th} stage shift register Gi is used as the first clock signal XCK02 of the (i+1)^{th} stage shift register Gi+1, and the initial output control signal CK02 of the (i+1)^{th} stage shift register Gi+1 is used as the first clock signal XCK01 of the i^{th} stage shift register Gi. The initial output control signals CK01 of shift registers of odd-numbered stages are used as the first clock signals XCK02 of shift registers of even-numbered stages, and the initial output control signals CK02 of the shift registers of even-numbered stages are used as the first clock signals XCK01 of the shift registers of odd-numbered stages.

Furthermore, on the premise that the normal outputting of the initial output signals and the first output signals by the shift registers of all stages can be ensured, it may further allow the shift registers of odd-numbered stages to receive the same first output control signal and the shift registers of even-numbered stages to receive the same first output control signal.

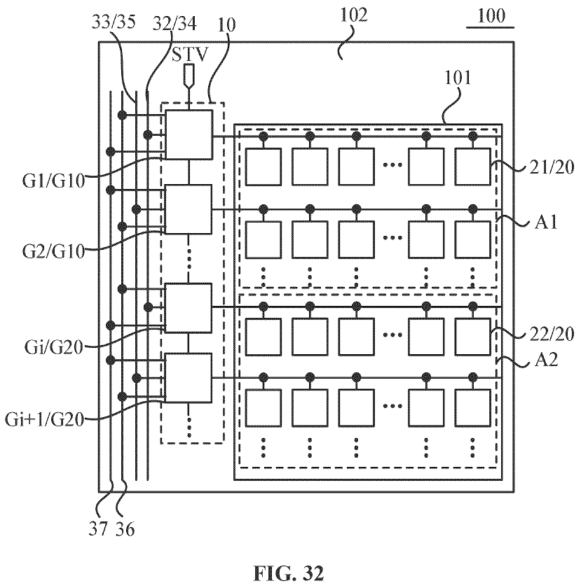

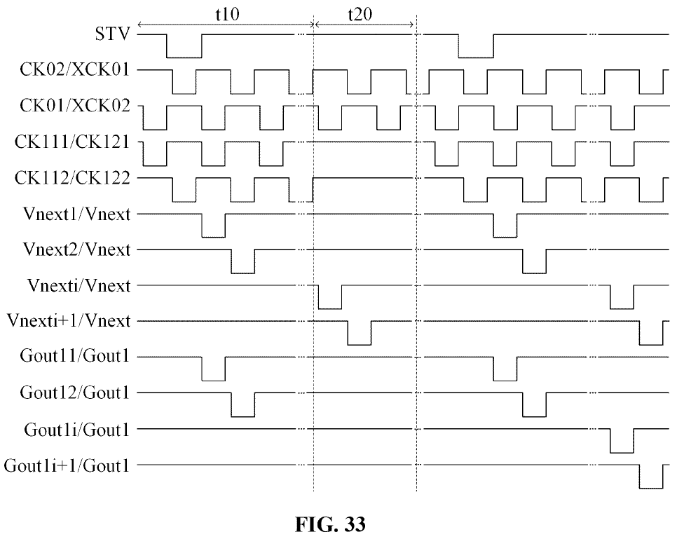

In an exemplary embodiment, reference is made to FIG. 32 and FIG. 33, in a case where the display panel 100 includes first shift registers G10 and second shift registers G20, and the pulse change frequency of the first output signals Gout1 (Gout11, Gout12) output by the first shift registers G10 is different from the pulse change frequency of the first output signals Gout1 (Gout1i, Gout1i+1) output by the second shift registers G20, if shift registers (G1, Gi) of odd-numbered stages receive the same first output control signal (CK111, CK121) and shift registers (G2, Gi+1) of even-numbered stages receive the same first output control signal (CK112, CK122), during the period in which the first shift registers G10 sequentially each output an active level of the initial output signal Vnext and an active level of the first output signal Gout1 (that is, in the first time period t10), the first output control signals (CK111, CK121) received by the shift registers (G1, Gi) of odd-numbered stages are consistent with the initial output control signals CK01 received by them respectively, and the first output control signals (CK112, CK122) received by the shift registers (G2, Gi+1) of even-numbered stages are consistent with the initial output control signals CK02 received by them respectively. While during the period in which the second shift registers G20 each sequentially output an active level of the initial output signal Vnext (that is, in the second time period t20), the first output signals Gout1 output by the second shift registers G20 continue to be the inactive level. At this time, the first output control signals (CK111, CK121) received by the shift registers (G1, Gi) of odd-numbered stages and the first output control signals (CK112, CK122) received by the shift registers (G2, Gi+1) of even-numbered stages are all kept at the invalid level. In this manner, on the premise of reducing the signals provided to the stages of shift registers, it can also realize that the output signals of different shift registers have different states, thereby ensuring that the display panel meets diversified functional requirements and facilitating the reduction in the cost of the driving chip and realization of the narrow bezel of the display panel.

It is to be noted that the setting methods of the first output control signal, the initial output control signal, and the first clock signal described above are all exemplary description of the embodiments of the present disclosure, which is not specifically limited in the embodiments of the present disclosure provided that the core inventive point of the embodiments of the present disclosure can be realized.

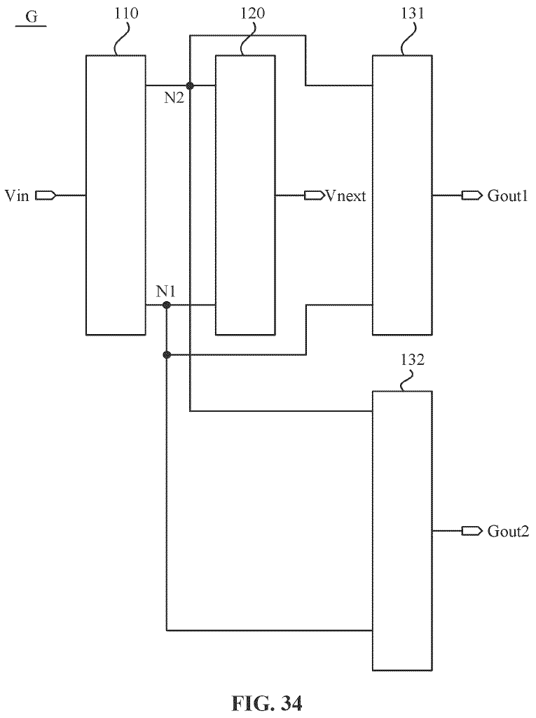

In one or more embodiments, FIG. 34 is a structural schematic diagram of another shift register according to an embodiment of the present disclosure. As shown in FIG. 34, the shift register G further includes a second output unit 132; and the second output unit 132 is configured to at least receive the signal of the first output node N1 and the signal of the second output node N2, and control a second output signal Gout2.

The initial output unit 120, the first output unit 131 and the second output unit 132 each receive the signals of the first output node N1 and the second output node N2, so that the signal of the first output node N1 and the signal of the second output node N2 may separately control the initial output signal Vnext output by the initial output unit 120, the first output signal Gout1 output by the first output unit 131, and the second output signal Gout2 output by the second output unit 132. In this case, the initial output signal Vnext output by the initial output unit 120 serves as the input signal Vin of another stage shift register, and the first output signal Gout1 and the second output signal Gout2 may each be used as a control signal of the preset module in the pixel circuit. At this time, the second output signal Gout2 may be different from the first output signal Gout1 so that the first output signal Gout1 and the second output signal Gout2 may respectively be the control signals for controlling the preset modules of the pixel circuits in different rows, or so that the first output signal Gout1 and the second output signal Gout2 may respectively be the control signals for controlling different preset modules in the same pixel circuit. In this manner, it facilitates the reduction in the number of shift registers in the drive circuit, thereby facilitating a reduction in the area occupied by the drive circuit, so that when the drive circuit is set in the non-display region of the display panel, it facilitates the realization of the narrow bezel of the display panel. The structure of the second output unit 132 may be the same as or different from the structure of the first output unit 131, which is not limited in the embodiments of the present disclosure.

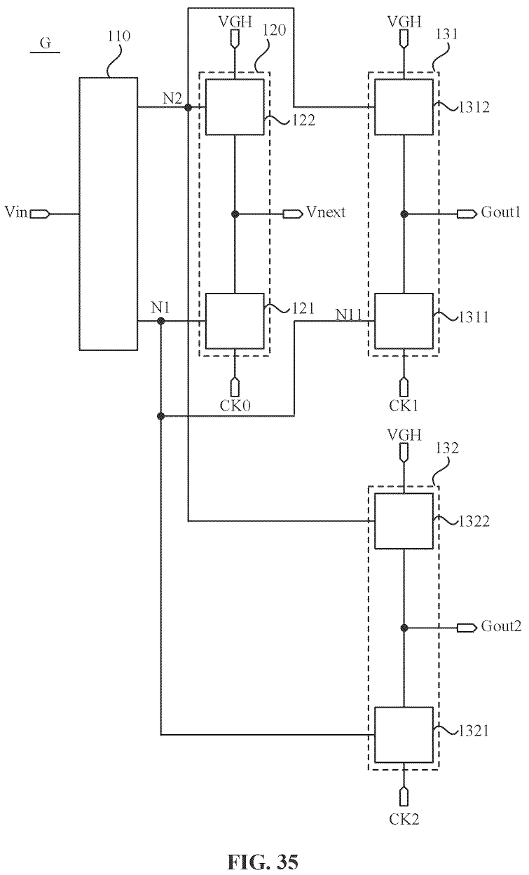

In one or more embodiments, FIG. 35 is a schematic structural diagram of another shift register according to an embodiment of the present disclosure, and as shown in FIG. 35, the second output unit 132 may include a third output module 1321 and a fourth output module 1322. The third output module 1321 at least receives the second output control signal CK2 and the signal of the first output node N1, and controls the second output signal Gout2. The fourth output module 1322 at least receives the first voltage signal and the signal of the second output node, and controls the second output signal.

The third output module 1321 at least receives the second output control signal CK2 and the signal of the first output node N1 so that the third output module 1321 may output the second output signal Gout2 under the control of the second output control signal CK2 and the signal of the first output node N1. The fourth output module 1322 at least receives the first voltage signal VGH and the signal of the second output node N2 so that the fourth output module 1322 may output the second output signal Gout2 under the control of the first voltage signal VGH and the signal of the second output node N2. At this time, the first output node N1, the second output node N2, the first voltage signal VGH, and the second output control signal CK2 can determine the polarity and amplitude of the second output signal Gout2.

In an exemplary embodiment, when the signal of the first output node N1 is an active level, the third output module 1321 may control the second output signal Gout2 to be consistent with the second output control signal CK2, and when the signal of the second output node N2 is an active level, the fourth output module 1322 may control the second output signal Gout2 to be consistent with the first voltage signal VGH.

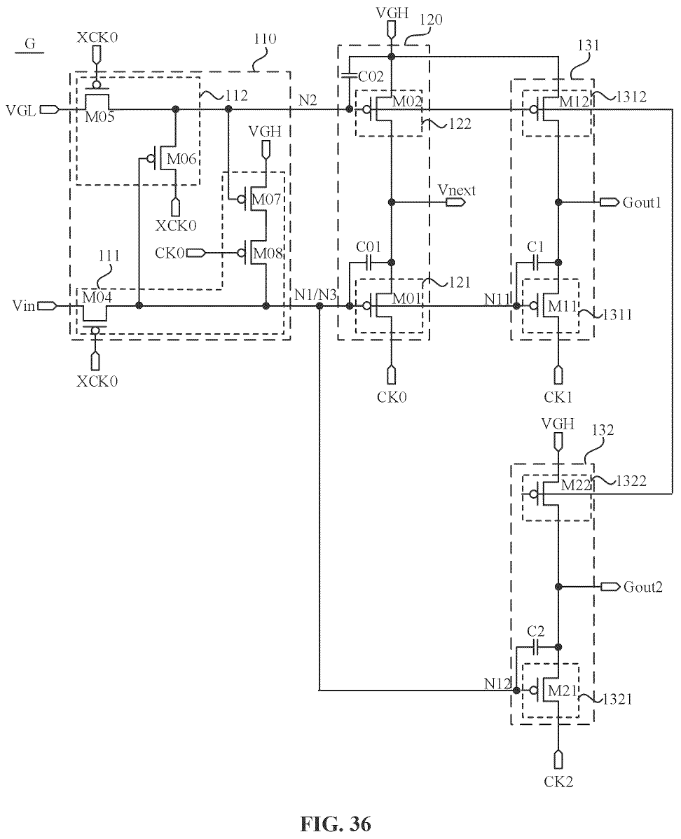

FIG. 36 is a schematic structural diagram of another shift register according to an embodiment of the present disclosure. As shown in FIG. 36, the third output module 1321 includes a fourth transistor M21. A first electrode of the fourth transistor M21 is configured to receive the second output control signal CK2, a second electrode of the fourth transistor M21 is configured to output the second output signal Gout2, a gate of the fourth transistor M21 is connected to the first output node N1 or the second node N12, and the first output node N1 is directly connected to the second node N12, that is, the signal of the first output node N1 is the same as the signal of the second node N12. In this way, the fourth transistor M21 may be turned on or off under the control of the signal of the first output node N1, when the signal of the first output node N1 controls the fourth transistor M21 to be turned on, the second output control signal CK2 received by the first electrode of the fourth transistor M21 is transmitted to the second electrode of the fourth transistor M21, so that the second output control signal CK2 serves as the second output signal Gout2 output by the second electrode of the fourth transistor M21.

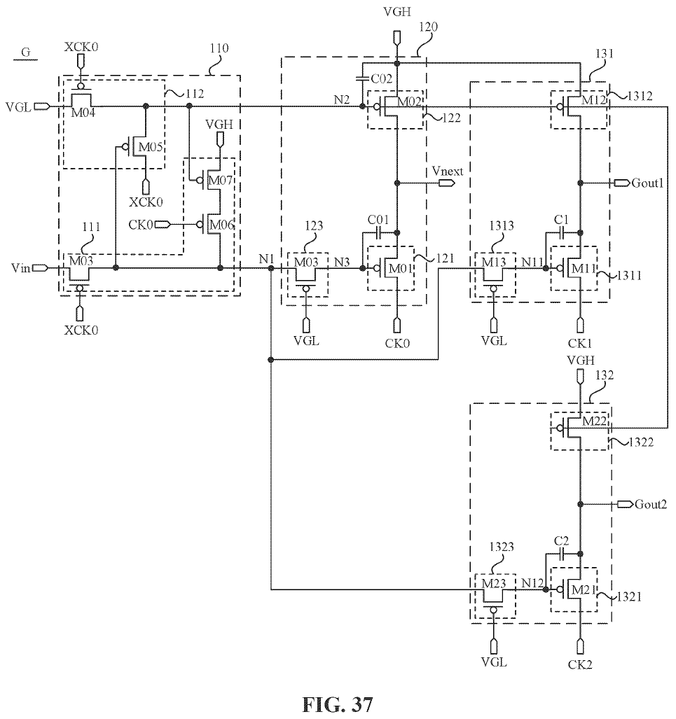

In another embodiment, FIG. 37 is a schematic structural diagram of another shift register according to an embodiment of the present disclosure. As shown in FIG. 37, the second output unit 13 may further include a second stabilization module 1323, the first output node N1 is connected to the second node N12 through the second stabilization module 1323, that is, the second node N12 and the first output node N1 are different nodes. The second stabilization module 1323 may isolate the first output node N1 from the second node N12, it is ensured that the signal of the first output node N1 and the signal of the second node N12 are relatively stable, and the accuracy of the second output signal Gout2 output by the fourth transistor M21 is prevented from being adversely affected by the fluctuation of the first output node N1 and/or the second node N12, thereby facilitating the improvement of the working stability of the shift register G, and further facilitating the improvement of the display effect of the display panel.

With continued reference to FIG. 37, the second stabilization module 1323 may include a sixth transistor M23. A first electrode of the sixth transistor M23 is connected to the first output node N1, a second electrode of the sixth transistor M23 is connected to the second node N12, and a gate of the sixth transistor M23 receives the second voltage signal VGL.

The second voltage signal VGL may control the sixth transistor M23 to maintain the on state continuously, so that the signal of the first output node N1 is substantially consistent with the signal of the second node N12. However, the turned-on sixth transistor M23 has a certain resistance, so that when the signal of the second node N12 electrically connected to the fourth transistor M21 changes, the sixth transistor M23 can reduce the change amount at which the signal of the first output node N1 changes with the signal of the second node N12. Similarly, when the signal of the first output node N1 changes, the sixth transistor M23 can also reduce the change amount at which the signal of the second node N12 changes with the signal of the first output node N1. Thus, by providing the sixth transistor M23 between the first output node N1 and the second node N12, the stability of the signals at the first output node N1 and the second node N12 can be ensured, thereby improving the stability of the second output signal Gout2 output by the fourth transistor M21.

On the basis of the above embodiments, with continued reference to FIG. 36 or FIG. 37, the fourth output module 1322 includes a fifth transistor M22. A first electrode of the fifth transistor M22 is configured to receive the first voltage signal VGH, a second electrode of the fifth transistor M22 is configured to output the second output signal Gout2, and a gate of the fifth transistor M22 is connected to the second output node N2. In this way, the fifth transistor M22 can be turned on or off under the control of the signal of the second output node N2, when the signal of the second output node N2 controls the fifth transistor M22 to be turned on, the first voltage signal VGH received by the first electrode of the fifth transistor M22 is transmitted to the second electrode, so that the first voltage signal VGH serves as the second output signal Gout2 output by the second electrode of the fifth transistor M22.

Furthermore, with reference to FIG. 36 or FIG. 37, the second output unit 132 may further include a second bootstrap capacitor C2. The second bootstrap capacitor C2 may be electrically connected between the second electrode of the fourth transistor M21 and the gate of the fourth transistor M21 so that when the second output signal Gout2 of the second electrode of the fourth transistor M21 hops from the high level to the low level or from the low level to the high level, the signal of the gate of the fourth transistor M21 may be controlled due to the coupling of the second bootstrap capacitor C2, to change with the second output signal Gout2, thereby ensuring that the signal at the gate of the fourth transistor M21 has a sufficiently high drive capability to drive the fourth transistor M21 to be turned on or off.

The second output control signal CK2 may be a pulse signal with a pulse change frequency of Fc2 such that the second output control signal CK2 includes a high level and a low level. In this manner, when a high-level second output signal Gout2 is required to be output, the first output node N1 controls the fourth transistor M21 to be turned on when the second output control signal CK2 is a high level, and/or the second output node N2 controls the fifth transistor M22 to be turned on, so that the second output signal Gout2 is consistent with the high level of the second output control signal CK2 and/or the first voltage signal VGH. When it is required to output a low-level second output signal Gout2, the first output node N1 controls the fourth transistor M21 to be turned on when the second output control signal CK2 is a low level, so that the second output signal Gout2 is consistent with the low level of the second output control signal CK2. With this arrangement, the second output signal Gout2 may be a pulse signal having a high level and a low level, thereby meeting the driving requirements of the shift register G.

It may be appreciated that the pulse change frequency Fc2 of the second output control signal CK2 may be the same or different from the pulse change frequency Fc1 of the first output control signal CK1, so that the pulse change frequency of the first output signal Gout1 may be the same as or different from the pulse change frequency of the second output signal Gout2, which is not limited in the embodiments of the present disclosure.

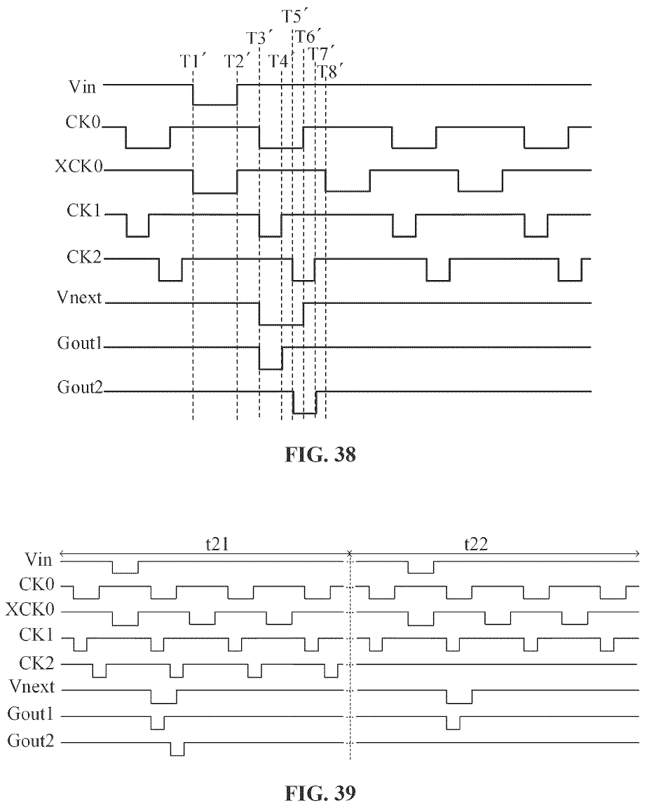

Illustratively, the case that each transistor of the shift register shown in FIG. 36 is a P-type transistor and the first output control signal CK1 and the second output control signal CK2 have the same pulse change frequency is taken as an example. FIG. 38 is a drive timing diagram of another shift register according to an embodiment of the present disclosure, with reference to FIG. 36 and FIG. 38, in the time from instant T1′ to instant T2′, the input signal Vin and the first clock signal XCK0 are each a low level so that the signal of the first output node N1 is an active level that controls the first initial output transistor M01, the first transistor M11 and the fourth transistor M21 to be turned on. As a result, the initial output control signal CK0 output by the first initial output transistor M01 serves as the initial output signal Vnext, the first output control signal CK1 output by the first transistor M11 serves as the first output signal Gout1, and the second output control signal CK2 output by the fourth transistor M21 serves as the second output signal Gout2, such that the initial output signal Vnext is kept consistent with the high level of the initial output control signal CK0, the first output signal Gout1 is kept consistent with the high level of the first output control signal CK1, and the second output signal Gout2 is kept consistent with the high level of the second output control signal CK2.

In the time from instant T2′ to instant T8′, although the input signal Vin is turned to a high level, the first clock signal XCK0 is kept at the high level, so that the high level of the input signal Vin cannot be transmitted to the first output node N1, and the signal of the first output node N1 remains as an active level.

At instant T3′, the initial output control signal CK0 hops to a low level so that the initial output signal Vnext is turned to a low level with the initial output control signal CK0, and at the same time the first output control signal CK1 hops to a low level so that the first output signal Gout1 also hops to a low level with the first output control signal CK1. At instant T4′, the first output control signal CK1 hops to a high level so that the first output signal Gout1 also hops to a high level with the first output control signal CK1. At instant T5′, the second output control signal CK2 hops to a low level so that the second output signal Gout2 also hops to a low level with the second output control signal CK2. At instant T6′, the initial output control signal CK0 hops to a high level, causing the initial output signal Vnext to hop to a high level with the initial output control signal CK0. At instant T7′, the second output control signal CK2 hops to a high level, causing the second output signal Gout2 to also hop to a high level with the second output control signal CK2. At instant T8′, the first clock signal XCK0 hops to a low level again so that the high-level input signal Vin is transmitted to the first output node N1, the signal of the first output node N1 controls the first initial output transistor M01, the first transistor M11 and the fourth transistor M21 to be turned off, so that the initial output signal Vnext no longer changes with the change of the initial output control signal CK0, the first output signal Gout1 no longer changes with the change of the first output control signal CK1, and the second output signal Gout2 no longer changes with the change of the second output control signal CK2, until the input signal Vin is turned to the low level again. In this way, the low-level time of the initial output signal Vnext may overlap the low-level time of the first output signal Gout1 and the low-level time of the second output signal Gout2, and the low level of the first output signal Gout1 and the low level of the second output signal Gout2 shift sequentially, so that the first output signal Gout1 and the second output signal Gout2 respectively controls signal refreshing of pixel circuits in different rows. Therefore, there is no need for providing a shift register G for pixel circuits in each row, the number of shift registers G in the drive circuit can be reduced, the structure of the drive circuit can be simplified, the dimension of the drive circuit can be reduced, and the realization of the narrow bezel of the display panel can be facilitated.

In one or more embodiments, the duration from an instant at which an effective pulse of the initial output control signal of an x^{th} stage shift register starts to an instant at which an effective pulse of the initial output control signal of a y^{th} stage shift register starts is W0, the duration of an effective pulse of the first output control signal of the x^{th} stage shift register is W1, the duration of an effective pulse of the second output control signal of the x^{th} stage shift register is W2, and W0≥(W1+W2).

The case that the shift register shown in FIG. 36 is the x^{th} stage shift register is taken as an example, with reference to FIG. 36 and FIG. 38, the effective pulse of the initial output signal Vnext of the x^{th} stage shift register is provided by the initial output control signal CK0 received by the x^{th} stage shift register, so that when the initial output control signal received by the x^{th} stage shift register is an effective pulse, the initial output signal of the x^{th} stage shift register is also an effective pulse. The effective pulse of the initial output signal of the y^{th} stage shift register is provided by the initial output control signal received by the y^{th} stage shift register so that when the initial output control signal received by the y^{th} stage shift register is an effective pulse, the initial output signal of the y^{th} stage shift register is also an effective pulse. Moreover, the initial output signal Vnext of the x^{th} stage shift register is the input signal of the y^{th} stage shift register so that the effective pulse of the initial output signal Vnext output by the x^{th} stage shift register and the effective pulse of the initial output signal output by the y^{th} stage shift register can shift sequentially. The effective pulse of the initial output control signal CK0 received by the x^{th} stage shift register and the effective pulse of the initial output control signal received by the y^{th} stage shift register need to shift sequentially, that is, there is a certain time interval W0 from the instant at which the effective pulse of the initial output control signal CK0 received by the x^{th} stage shift register starts to the instant at which the effective pulse of the initial output control signal received by the y^{th} stage shift register starts. In a case where the W0 is greater than (W1+W2), it is possible that before the y^{th} stage shift register starts to output the effective pulse of the initial output signal, the effective pulse of the first output signal Gout1 and the effective pulse of the second output signal Gout2 output by the x^{th} stage shift register shift sequentially, thereby ensuring that the effective pulse of the first output signal and the effective pulse of the second output signal output by each stage shift register shift sequentially and the time of the effective pulse does not overlap.

It is to be noted that the above description illustrates simply by taking the case that the pulse change frequency of the first output control signal CK1 is the same as the pulse change frequency of the second output control signal CK2 as an example. However, in the embodiments of the present disclosure, the pulse change frequency of the first output control signal CK1 and the pulse change frequency of the second output control signal CK2 may be set according to practical requirements, which is not limited in the embodiments of the present disclosure.

In one or more embodiments, when the pulse change frequency of the first output control signal CK1 is Fc1 and the pulse change frequency of the second output control signal CK2 is Fc2, within at least a part of the time period of the working process of the display panel, Fc1=Fc2; and/or, within at least another part of the time period of the working process of the display panel, Fc1≠Fc2.

Illustratively, FIG. 39 is a drive timing diagram of another shift register according to an embodiment of the present disclosure. With reference to FIG. 36 and FIG. 39, the first output control signal CK1 and the second output control signal CK2 have the same pulse change frequency in the time period t21 so that the first output signal Gout1 and the second output signal Gout2 have the same pulse change frequency, and thus the data refresh rate of the pixel circuit controlled by the first output signal Gout1 can be the same as the data refresh rate of the pixel circuit controlled by the second output signal Gout2. However, in the time period t22, the first output control signal CK1 is different from the second output control signal CK2, for example, the second output control signal CK2 is continuously kept at the high level, so that the pulse change frequency of the second output control signal CK2 is less than the pulse change frequency of the first output control signal CK1. At this time, the pulse change frequency of the first output signal Gout1 and the pulse change frequency of the second output signal Gout2 are different, and the data refresh rate of the pixel circuit controlled by the first output signal Gout1 can be greater than the data refresh rate of the pixel circuit controlled by the second output signal Gout2. In this manner, by setting the pulse change frequencies of the first output control signal CK1 and the second output control signal CK2, the pulse change frequency of the first output signal Gout1 and the pulse change frequency of the second output signal Gout2 can meet the data refresh requirements of the pixel circuits in the display panel, thereby enabling the display panel to meet diversified display requirements.

In another embodiment, when the pulse change frequency of the initial output control signal is Fc0, the pulse change frequency of the first output control signal is Fc1 and the pulse change frequency of the second output control signal is Fc2, within at least a part of the time period of the working process of the display panel, Fc0≥Fc1, and/or Fc0≥Fc2.

For example, with continued reference to FIG. 36 and FIG. 39, within the time period t21, the initial output control signal CK0 has the same pulse change frequency as the first output control signal CK1 and the second output control signal CK2, so that the initial output signal Vnext has the same pulse change frequency as the first output signal Gout1 and the second output signal Gout2. In the time period t22, the initial output control signal CK0 has the same pulse change frequency as the first output control signal CK1, while the initial output control signal CK0 has a different pulse change frequency from the second output control signal CK2, so that the initial output signal Vnext has the same pulse change frequency as the first output signal Gout1, while the initial output signal Vnext has a different pulse change frequency from the second output signal Gout2. In this manner, the refresh rate of the pixel circuit controlled by the second output signal Gout2 is different from the driving frequency of the shift register, thereby meeting the special display requirements of the display panel.

It may be appreciated that the above illustrates simply by taking the case that within at least a part of the time period of the working process of the display panel, the pulse change frequency of the first output control signal CK1 is greater than the pulse change frequency of the second output control signal CK2 as an example. However, in the embodiments of the present disclosure, it may also set the pulse change frequency of the first output control signal CK1 to less than the pulse change frequency of the second output control signal CK2. Moreover, in the above description, it is simply taken as an example that within at least a part of the time period of the working process of the display panel, the pulse change frequency of the initial output control signal CK0 is the same as the pulse change frequency of the first output control signal CK1 and is different from the pulse change frequency of the second output control signal CK2. However, In one or more embodiments of the present disclosure, the pulse change frequency of the initial output control signal CK0 may be different from the pulse change frequency of the first output control signal CK1 and the pulse change frequency of the second output control signal CK2, or the pulse change frequency of the initial output control signal CK0 may be the same only as the pulse change frequency of the second output control signal CK2, which may be designed according to practical requirements and not limited in the embodiments of the present disclosure.

It may further be appreciated that the above illustrates simply by taking the case that when the initial output control signal CK0 has the same pulse change frequency as the first output control signal CK1 and the second output control signal CK2, the time of the active level of the first output signal Gout1 and the time of the active level of the second output signal Gout2 both overlap with the time of the active level of the initial output signal Vnext as an example. However, in other embodiments of the present disclosure, when the initial output control signal CK0 has the same pulse change frequency as the first output control signal CK1 and the second output control signal CK2, the time of the active level of the first output signal Gout1 and the time of the active level of the second output signal Gout2 may also be after the time of the active level of the initial output signal Vnext, which may have the same effect as that in the above embodiments, the reference may be made to the above description for the same parts, which is not repeatedly described here.

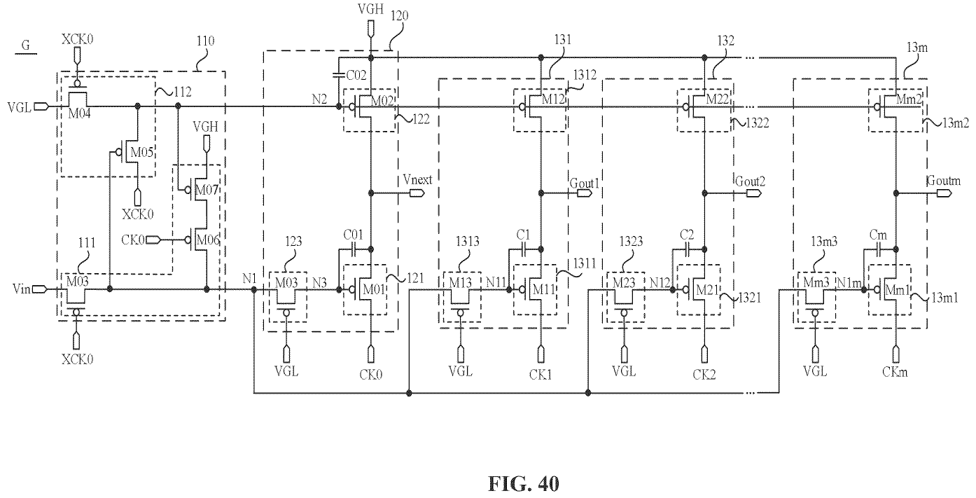

In other embodiments, FIG. 40 is a schematic structural diagram of another shift register according to an embodiment of the present disclosure. As shown in FIG. 40, the shift register may further include an m^{th} output unit 13m, m≥3; and the m^{th} output unit 13m is configured to at least receive the signal of the first output node N1 and the signal of the second output node N2 and control an m^{th} output signal. In this case, the shift register is provided with a first output unit 131, a second output unit 132, . . . , and the m^{th} output unit 13m, that is, m output units in total. The m output units respectively output the first output signal Gout1, the second output signal Gout2, . . . , and the m^{th} output signal Goutm, that is, m output signals in total, and these m output signals may respectively control the preset modules in different pixel circuits to be turned on or off, so that different pixel circuits can share one shift register G, which facilitates the reduction in the number of shift registers G provided in the drive circuit, facilitates simplification of the structure of the drive circuit, reduces the dimension of the drive circuit, and further facilitates the realization of the narrow bezel of the display panel.

In one or more embodiments, with continued reference to FIG. 40, the structures of the output units from the first output unit 131 to the m^{th} output unit 13m may be substantially the same, that is, similar to the structure of the first output unit 131, the m^{th} output unit 13m may include a (2m−1)^{th} output module 13m1 and a 2m^{th} output module 13m2. The (2m−1)^{th} output module 13m1 at least receives an m^{th} output control signal CKm and the signal of the first output node N1, and controls the m^{th} output signal Goutm. The 2m^{th} output module 13m2 at least receives the first voltage signal VGH and the signal of the second output signal N2, and controls the m^{th} output signal Goutm.

The (2m−1)^{th} output module 13m1 may include a (3m−2)^{th} transistor Mm1, a first electrode of the (3m−2)^{th} transistor Mm1 is configured to receive the m^{th} output control signal CKm, a second electrode of the (3m−2)^{th} transistor Mm1 is configured to output the m^{th} output signal Goutm, and a gate of the (3m−2)^{th} transistor Mm1 is connected to the first output node N1 or an m^{th} node N1m. The first output node N1 is directly connected to the m^{th} node N1m, or the first output node N1 is connected to the m^{th} node N1m through an m^{th} stabilization module 13m3, and the m^{th} stabilization module 13m3 may stabilize the signal of the first output node N1 and the signal of the m^{th} node N1m so that the signal of the first output node N1 is substantially the same as the signal of the m^{th} node N1m. In this way, the (3m−2)^{th} transistor Mm1 may be turned on or off under the control of the signal of the first output node N1, and when the signal of the first output node N1 controls the (3m−2)^{th} transistor Mm1 to be turned on, the (3m−2)^{th} transistor Mm1 may output the m^{th} output control signal CKm as the m^{th} output signal Goutm.

Correspondingly, the 2m^{th} output module 13m2 may include a (3m−1)^{th} transistor Mm2, a first electrode of the (3m−1)^{th} transistor Mm2 receives the first voltage signal VGH, a second electrode of the (3m−1)^{th} transistor Mm2 is configured to output the m^{th} output signal Goutm, and a gate of the (3m−1)^{th} transistor Mm2 is connected to the second output node N2. In this way, the (3m−1)^{th} transistor Mm2 may be turned on or off under the control of the second output node N2, and when the signal of the second output node N2 controls the (3m−1)^{th} transistor Mm2 to be turned on, the (3m−1)^{th} transistor Mm2 may output the first voltage signal VGH as the m^{th} output signal Goutm.

In one or more embodiments, when the m^{th} output unit includes the m^{th} stabilization module 13m3, the m^{th} stabilization module 13m3 may include a 3m^{th} transistor Mm3, a first electrode of the 3m^{th} transistor Mm3 is connected to the first output node N1, a second electrode of the 3m^{th} transistor Mm3 is connected to the m^{th} node Nm, and a gate of the 3m^{th} transistor Mm3 receives the second voltage signal VGL.

Furthermore, the m^{th} output unit may further include an m^{th} bootstrap capacitor Cm, the m^{th} bootstrap capacitor Cm may be electrically connected between the second electrode of the (3m−2)^{th} transistor Mm1 and the gate of the (3m−2)^{th} transistor Mm1 so that a sufficiently high driving capacity of the signal at the gate of the (3m−2)^{th} transistor Mm1 for driving the (3m−2)^{th} transistor Mm1 to be turned or off can be ensured.

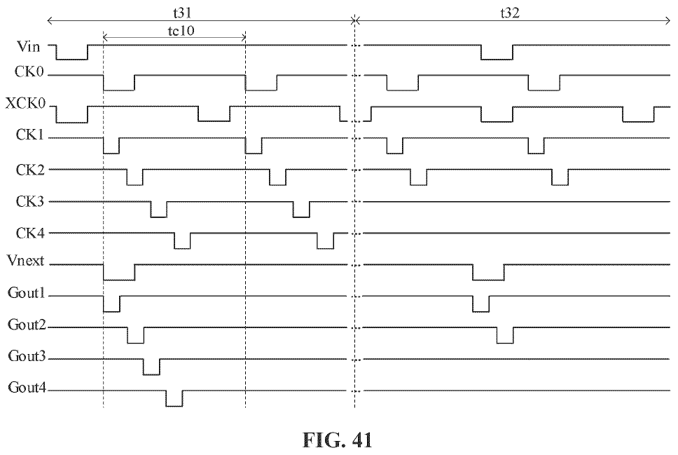

FIG. 41 is a drive timing diagram of another shift register according to an embodiment of the present disclosure, it may be appreciated that the structure of the m^{th} output unit 13m is substantially the same as the structure of the first output unit 131, and has a working principle similar to that of the first output unit 131. Reference may be made to the above description for the similarities, and here it only instantiates the relationship between the signals output by the output units. As shown in FIG. 41, m equal to 4 is taken as an example, in a clock cycle tc, the active level of the first output control signal CK1, the active level of the second output control signal CK2, the active level of the third output control signal CK3, and the active level of the fourth output control signal CK4 may shift sequentially and not overlap with each other, in this case, the active level of the first output signal Gout1 output by the first output unit, the active level of the second output signal Gout2 output by the second output unit, the active level of the third output signal Gout3 output by the third output unit and the active level of the fourth output signal Gout4 output by the fourth output unit may shift sequentially, so that the first output signal Gout1, the second output signal Gout2, the third output signal Gout3 and the fourth output signal Gout4 can scan different pixel circuits row by row.

In one or more embodiments, the duration from the instant at which the effective pulse of the initial output control signal of the x^{th} stage shift register starts to the instant at which the effective pulse of the initial output control signal of the y^{th} stage shift register starts is W0, the duration of the effective pulse of the first output control signal of the x^{th} stage shift register is W1, the duration of the effective pulse of the second output control signal of the x^{th} stage shift register is W2, the duration of the effective pulse of the m^{th} output control signal of the x^{th} stage shift register is Wm, and W0≥Σᵢ₌₁^{m} Wi.

Illustratively, it is taken as an example that the shift register shown in FIG. 40 is the x^{th} stage shift register, with reference to FIG. 41 and FIG. 40, when the initial output signal Vnext of the x^{th} stage shift register is the input signal Vin of the y^{th} stage shift register, and the effective pulse of the initial output signal Vnext output by the x^{th} stage shift register and the effective pulse of the initial output signal output by the y^{th} stage shift register shift sequentially, the effective pulse of the initial output control signal received by the x^{th} stage shift register and the effective pulse of the initial output control signal received by the y^{th} stage shift register shift sequentially, that is, the time when the effective pulse of the initial output control signal received by the x^{th} stage shift register starts to the time when the effective pulse of the initial output control signal received by the y^{th} stage shift register starts has a certain interval duration W0. When W0≥Σᵢ₌₁^{m} Wi, it is possible that, before the y^{th} stage shift register starts to output the effective pulse of the first output signal, the effective pulse of the first output signal Gout1, the effective pulse of the second output signal Gout2, the effective pulse of the third output signal Gout3 and the effective pulse of the fourth output signal Gout4 output by the x^{th} stage shift register shift sequentially, thereby ensuring that the effective pulse of the first output signal, the effective pulse of the second output signal, the effective pulse of the third output signal Gout3 and the effective pulse of the fourth output signal Gout4 output by the shift register of each stage shift sequentially and the times of these effective pulses do not overlap with each other.

In one or more embodiments, within at least a part of the time period of the working process of the display panel, the pulse change frequency Fc1 of the first output control signal CK1 to the pulse change frequency Fcm of the m^{th} output control signal CKm are all equal to each other; or at least two among the pulse change frequency of the first output control signal CK1 to the pulse change frequency of the m^{th} output control signal CKm are not equal.

Illustratively, m equal to 4 is taken as an example. As shown in FIG. 41, in the time period t31, the pulse change frequency Fc1 of the first output control signal CK1 to the pulse change frequency Fcm of the fourth output control signal CK4 are all equal, at this time, the first output unit to the fourth output unit may sequentially output an active level of the first output signal Gout1, an active level of the second output signal Gout2, an active level of the third output signal Gout3 and an active level of the fourth output signal Gout4, thereby enabling the pixel circuits respectively controlled by the first output signal Gout1, the second output signal Gout2, the third output signal Gout3 and the fourth output signal Gout4 to have the same data refresh rate. In the time period t32, the pulse change frequency Fc1 of the first output control signal CK1 is different from the pulse change frequency Fcm of the fourth output signal CK4, for example, the fourth output control signal CK4 is an inactive level continuously, while the first output control signal CK1 includes an active level and an inactive level, that is, the pulse change frequency of the first output control signal CK1 is greater than the pulse change frequency of the fourth output control signal CK4, so that the first output signal Gout1 output by the first output unit includes an active level while the fourth output signal Gout4 output by the fourth output unit is an inactive level. Thus, the pixel circuits controlled by the first output signal Gout1 perform data refreshing during this time period, and the pixel circuits controlled by the fourth output signal Gout4 may not perform data refreshing during this time period, that is, the data refresh rate of the pixel circuits controlled by the first output signal Gout1 may be greater than the data refresh rate of the pixel circuits controlled by the fourth output signal Gout4, thereby enabling the pixel circuits of the display panel to perform data refreshing according to requirements, and meeting the display requirements of low power consumption and high display quality.

When the pulse change frequency of the initial output control signal CK1 is Fc0, and the pulse change frequency of the m^{th} output control signal CKm is FcM, within at least a part of the time period of the working process of the display panel, Fc0≥Fcm.

m equal to 4 is taken as an example. With continued reference to FIG. 41, in the time period t32, the initial output control signal CK0 has the same pulse change frequency as the first output control signal CK1 and the second output control signal CK2, while the pulse change frequency of the initial output control signal CK0 is greater than the pulse change frequency of the third output control signal CK3 and the pulse change frequency of the fourth output control signal CK4, so that the initial output signal Vnext has the same pulse change frequency as the first output signal Gout1 and the second output signal Gout2, while the pulse change frequency of the initial output signal Vnext is greater than the pulse change frequency of the third output signal Gout3 and the pulse change frequency of the fourth output signal Gout4. As a result, the refresh rate of the pixel circuits controlled by the third output signal Gout3 and the refresh rate of the pixel circuits controlled by the fourth output signal Gout4 are less than the driving frequency of the shift register, thereby meeting the special display requirements of the display panel.

It may be appreciated that the above description simply takes as an example that the pulse change frequency of the initial output control signal CK0 is greater than the pulse change frequency of the third output control signal CK3 and the pulse change frequency of the fourth output control signal CK4 for illustration. However, in some embodiments of the present disclosure, the pulse change frequency of the initial output control signal CK0 may be greater than any one of the pulse change frequency of the first output control signal CK1, the pulse change frequency of the second output control signal CK2, the pulse change frequency of the third output control signal CK3 and the pulse change frequency of the fourth output control signal CK4, which may be designed according to practical requirements, and is not limited in the embodiments of the present disclosure.

It is to be noted that FIG. 41 only illustratively shows the situation of the output control signals and the output signals in a case of m equal to 4. However, m may be equal to any integer number greater than or equal to 3, such as 3, 5, or 6. As the value of m increases or decreases, the pulse change frequencies of the output control signals may decrease or increase therewith, to ensure that the effective pulses of the output signals output by the output units can shift sequentially, and reference may be made to the above descriptions for similarities, which is not described here.

Based on the same inventive concept, a display device is further provided according to the embodiments of the present disclosure. The display device includes the display panel according to the embodiments of the present disclosure. Therefore, the display device has technical features of the display panel and the driving method according to the embodiments of the present disclosure, and may achieve beneficial effects of the display panel according to the embodiments of the present disclosure. For the similarities, reference may be made to the foregoing description of the display panel according to the embodiments of the present disclosure, and those similarities are not described herein again.

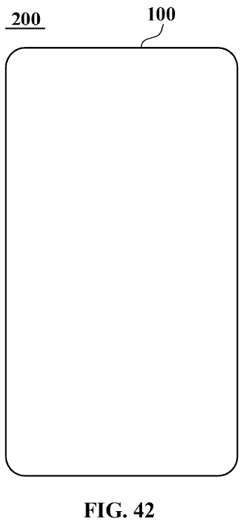

FIG. 42 is a schematic structural diagram of a display device according to an embodiment of the present disclosure. As shown in FIG. 42, the display device 200 includes the display panel 100 according to the embodiments of the present disclosure. The display device 200 according to the embodiment of the present disclosure may be any electronic product with a display function, including but not limited to, phones, televisions, notebook computers, desktop displays, tablet computers, digital cameras, smart bracelets, smart glasses, in-vehicle displays, medical equipment, industry-controlling equipment, touch interactive terminals, etc., which will not be particularly limited in the embodiments of the present disclosure.

It should be appreciated that operation processes of the various forms of pixel circuits shown above may be used with the stages reordered, some added, or deleted. For example, the stages in the operation processes of the pixel circuits recorded in the present disclosure may be performed in parallel, may be performed in sequence, or may be performed in different sequences, which is not limited herein as long as the expected result of the technical solutions of the present disclosure can be realized.

The above-mentioned embodiments do not constitute a limitation on the protection scope of the present disclosure. It is to be appreciated by the person skilled in the art that various modifications, combinations, sub-combinations, and substitutions may be made according to design requirements and other factors. Any modifications, equivalent substitutions, improvements and the like within the spirit and principle of the present disclosure shall fall within the protection scope of the present disclosure.

What is claimed is:

1. A display panel, comprising: a drive circuit, wherein the drive circuit comprises N cascaded stages of shift registers, wherein N≥2;
a shift register of the N cascaded stages of shift registers comprises a control unit, an initial output unit and a first output unit;
wherein the control unit is configured to at least receive an input signal and control a signal of a first output node and a signal of a second output node;
the initial output unit is configured to at least receive the signal of the first output node and the signal of the second output node, and control an initial output signal;
the initial output signal of an x^{th} stage shift register is the input signal of a y^{th} stage shift register, 1≤x≤N, and 1≤y≤N; and
the first output unit is configured to at least receive the signal of the first output node and the signal of the second output node, and control a first output signal.

2. The display panel according to claim 1, wherein the initial output signal has a pulse change frequency of F0, and the first output signal has a pulse change frequency of F1; wherein
within at least a part of a time period of a working process of the display panel, F0≠F1.

3. The display panel according to claim 2, wherein within at least a part of the time period of the working process of the display panel, F0>F1.

4. The display panel according to claim 1, wherein the initial output unit comprises a first initial output module and a second initial output module;
the first initial output module is configured to at least receive an initial output control signal and the signal of the first output node, and control the initial output signal; and
the second initial output module is configured to at least receive a first voltage signal and the signal of the second output node, and control the initial output signal.

5. The display panel according to claim 4, wherein the first initial output module comprises a first initial output transistor;
wherein a first electrode of the first initial output transistor is configured to receive the initial output control signal, a second electrode of the first initial output transistor is configured to output the initial output signal, and a gate of the first initial output transistor is connected to the first output node or a third output node; and
the first output node is directly connected to the third output node, or the first output node is connected to the third output node by an initial stabilization module.

6. The display panel according to claim 4, wherein the second initial output module comprises a second initial output transistor;
wherein a first electrode of the second initial output transistor is configured to receive the first voltage signal, a second electrode of the second initial output transistor is configured to output the initial output signal, and a gate of the second initial output transistor is connected to the second output node.

7. The display panel according to claim 5, wherein the initial stabilization module comprises a third initial output transistor;
wherein a first electrode of the third initial output transistor is connected to the first output node, a second electrode of the third initial output transistor is connected to the third output node, and a gate of the third initial output transistor is configured to receive a second voltage signal.

8. The display panel according to claim 7, wherein the first voltage signal is a high-level signal, and the second voltage signal is a low-level signal.

9. The display panel according to claim 4, wherein the first output unit comprises a first output module and a second output module;
the first output module is configured to at least receive a first output control signal and the signal of the first output node, and control the first output signal; and
the second output module is configured to at least receive the first voltage signal and the signal of the second output node, and control the first output signal.

10. The display panel according to claim 9, wherein the first output module comprises a first transistor;
wherein a first electrode of the first transistor is configured to receive the first output control signal, a second electrode of the first transistor is configured to output the first output signal, and a gate of the first transistor is connected to the first output node or a first node; and
the first output node is directly connected to the first node, or the first output node is connected to the first node by a first stabilization module.

11. The display panel according to claim 10, wherein the second output module comprises a second transistor;
wherein a first electrode of the second transistor is configured to receive the first voltage signal, a second electrode of the second transistor is configured to output the first output signal, and a gate of the second transistor is connected to the second output node.

12. The display panel according to claim 11, wherein the first stabilization module comprises a third transistor;
wherein a first electrode of the third transistor is connected to the first output node, a second electrode of the third transistor is connected to the first node, and a gate of the third transistor is configured to receive a second voltage signal.

13. The display panel according to claim 9, wherein the initial output control signal has a pulse change frequency of Fc0, and the first output control signal has a pulse change frequency of Fc1; wherein within at least a part of a time period of a working process of the display panel, Fc0≠Fc1.

14. The display panel according to claim 13, wherein Fc0>Fc1.

15. The display panel according to claim 9, wherein a working process of the display panel comprises a first time period and a second time period;
wherein in the first time period, when the initial output control signal is an effective pulse, the first output control signal is an effective pulse; and
in the second time period, when the initial output control signal is an effective pulse, the first output control signal is an ineffective pulse.

16. The display panel according to claim 9, wherein the display panel comprises a pixel circuit, and the first output signal of the drive circuit is a control signal of a preset module of the pixel circuit;
when the first output signal is an effective pulse, the preset module is turned on; and
when the first output signal is an ineffective pulse, the preset module is turned off.

17. The display panel according to claim 16, wherein the preset module comprises a P-channel metal oxide semiconductor (PMOS) type transistor, and the first output signal is the control signal of the PMOS type transistor, wherein when the first output signal is a low-level signal, the first output signal is an effective pulse and controls the PMOS type transistor to be turned on; or
the preset module comprises an N-channel metal oxide semiconductor (NMOS) type transistor, and the first output signal is the control signal of the NMOS type transistor, wherein when the first output signal is a high-level signal, the first output signal is an effective pulse and controls the NMOS type transistor to be turned on.

18. The display panel according to claim 16, wherein a working process of the display panel comprises a first mode and a second mode;
wherein in the first mode, the first output control signal has a pulse change frequency of Fc11, and in the second mode, the first output control signal has a pulse change frequency of Fc12, wherein Fc11≠Fc12.

19. The display panel according to claim 18, wherein in the first mode, the first output signal has a pulse change frequency of Fs1, and in the second mode, the first output signal has a pulse change frequency of Fs2, wherein Fs1≠Fs2.

20. A display device, comprising the display panel according to claim 1.
